(19) United States
(12) Patent Application Publication
(10) Pub. No.: US 2026/0273923 A1
(43) Pub. Date: Sep. 17, 2026

(54) INKJET PRINTING APPARATUS, INKJET PRINTING METHOD USING THE SAME, ELECTRONIC DEVICE INCLUDING DISPLAY DEVICE INCLUDING LIGHT-EMITTING ELEMENT MANUFACTURED BY INKJET PRINTING METHOD

(71) Applicant: Samsung Display Co., Ltd., Yongin-si (KR)

(72) Inventor: Kenji KUDO, Yokohama-shi (JP)

(21) Appl. No.: 19/443,717

(22) Filed: Jan. 8, 2026

(30) Foreign Application Priority Data
Mar. 14, 2025 (JP) 2025-041405

(51) Int. Cl. B41J 2/045; H10K 71/13

(52) U.S. Cl. CPC B41J 2/04508; B41J 2/0457; B41J 2/04573; B41J 2/04581; B41J 2/0459; B41J 2/04591; B41J 2/04593; H10K 71/135

(57) ABSTRACT

An inkjet printing apparatus includes: a normal nozzle unit configured to discharge a first amount of ink in response to a first driving signal; a correction nozzle unit configured to discharge a second amount of the ink different from the first amount in response to a second driving signal; a driving signal generation unit configured to generate the first driving signal and the second driving signal to provide the first driving signal and the second driving signal to the normal nozzle unit and the correction nozzle unit; and a correction unit configured to receive a correction data and to provide a correction parameter corresponding to the correction data to the driving signal generation unit, wherein the driving signal generation unit is configured to generate the second driving signal based on the correction parameter.

### CROSS-REFERENCE TO RELATED APPLICATION

The present application claims priority to and the benefit of Japanese Patent Application No. JP 2025-041405, filed on Mar. 14, 2025, in the Japanese Intellectual Property Office, the entire disclosure of which is incorporated herein by reference.

### BACKGROUND

Aspects of some embodiments of the present disclosure herein relate to an inkjet printing apparatus, an inkjet printing method using the same, an electronic device including a display device including a light-emitting element manufactured by the inkjet printing method.

An electronic device, such as a smartphone, a digital camera, a notebook computer, a navigator, a smart television, or the like providing a user with a video generally includes a display device for displaying an image. The display device generates an image, and provides the user with the generated image through a display screen.

An organic light-emitting display device among display devices includes light-emitting elements for generating light. Each of the light-emitting elements includes an anode, an emission layer, and a cathode. Holes and electrons are injected to the emission layer from the anode and cathode to form excitons, and the light-emitting elements emit light while the excitons are transitioned to the ground state.

In manufacturing the light-emitting elements, the emission layer may be manufactured by an inkjet printing apparatus. An organic material (or ink) for forming the emission layer may be discharged onto a light-emitting area of a substrate from the inkjet printing apparatus to form the emission layer.

The emission layer may be provided in various sizes according to the resolution of the display device and the type of pixels. A target ink amount corresponding to the size of the emission layer may be provided to the light-emitting elements to form the emission layer. In order to provide the target ink amount to the emission layer, it may be desirable to precisely control an ink amount discharged from a nozzle.

The above information disclosed in this Background section is only for enhancement of understanding of the background and therefore the information discussed in this Background section does not necessarily constitute prior art.

### SUMMARY

Aspects of some embodiments of the present disclosure include an inkjet printing apparatus capable of providing a target ink amount to an emission layer more precisely, an inkjet printing method using the same, and an electronic device including a display device including light-emitting elements manufactured by the inkjet printing method.

Aspects of some embodiments of the present disclosure include an inkjet printing apparatus including a normal nozzle unit configured to discharge a first amount of ink in response to a first driving signal, a correction nozzle unit configured to discharge a second amount of the ink different from the first amount in response to a second driving signal, a driving signal generation unit configured to generate the first driving signal and the second driving signal to provide the first driving signal and the second driving signal to the normal nozzle unit and the correction nozzle unit, and a correction unit configured to be provided with correction data and provide a correction parameter corresponding to the correction data to the driving signal generation unit, wherein the driving signal generation unit may generate the second driving signal based on the correction parameter.

Aspects of some embodiments of the present disclosure, an inkjet printing method may include setting correction data, receiving print data including first grayscale data, second grayscale data, and correction data, activating a normal nozzle unit to a discharge state based on the first grayscale data, discharging a first amount of ink to a light-emitting area of a light-emitting element through the normal nozzle unit driven by a first driving signal, activating a correction nozzle unit to a discharge state based on the second grayscale data, generating a second driving signal based on a correction parameter corresponding to the correction data, and discharging a second amount of the ink different from the first amount to the light-emitting area through the correction nozzle unit driven by the second driving signal.

Aspects of some embodiments of the present disclosure, an electronic device may include a display device configured to display an image, wherein the display device may include a light-emitting element manufactured by an inkjet printing method, wherein the inkjet printing method may include setting correction data, receiving print data including first grayscale data, second grayscale data, and correction data, activating a normal nozzle unit to a discharge state based on the first grayscale data, discharging a first amount of ink to a light-emitting area of a light-emitting element through the normal nozzle unit driven by a first driving signal, activating a correction nozzle unit to a discharge state based on the second grayscale data, generating a second driving signal based on a correction parameter corresponding to the correction data, and discharging a second amount of the ink different from the first amount to the light-emitting area through the correction nozzle unit driven by the second driving signal.

### BRIEF DESCRIPTION OF THE DRAWINGS

The accompanying drawings are included to provide a further understanding of embodiments according to the present disclosure, and are incorporated in and constitute a part of this specification. The drawings illustrate aspects of some embodiments of the present disclosure and, together with the description, serve to explain aspects of some embodiments of the present disclosure. In the drawings:

FIG. 1 is a perspective view of a display device including pixels including emission layers manufactured by an inkjet printing apparatus according to some embodiments of the present disclosure;

FIG. 2 illustrates an example cross section of the display device shown in FIG. 1;

FIG. 3 illustrates an example cross section of a display panel shown in FIG. 2;

FIG. 4 illustrates an example cross section configuration of any one pixel among the pixels of the display panel shown in FIG. 3;

FIG. 5 shows the configuration of an inkjet printing apparatus according to some embodiments of the present disclosure;

FIG. 6 shows the configuration of an inkjet head unit shown in FIG. 5;

FIG. 7 is a cross-sectional view cut along line I-I’ shown in FIG. 6;

FIG. 8 shows any one nozzle unit shown in FIG. 7;

FIG. 9 is a drawing for explaining a process in which ink is provided to an light-emitting area via the nozzle unit shown in FIG. 8;

FIG. 10 shows waveforms of driving signals generated by a driving signal generation unit shown in FIGS. 7 and 8;

FIGS. 11A and 11B are drawings for explaining an operation of a nozzle unit to which a first driving signal is applied;

FIGS. 12A to 12C are drawings for explaining an operation of a nozzle unit to which a second driving signal is applied;

FIG. 13 illustrates various example waveforms of the second driving signal shown in FIG. 10;

FIG. 14 is a block diagram of an inkjet printing apparatus according to some embodiments of the present disclosure;

FIG. 15 shows nozzle units that may be selected according to grayscale data able to be provided to first to n-th nozzle columns;

FIG. 16 shows, as a table, nozzle units that may be selected according to grayscale data;

FIG. 17 is a drawing for explaining an operation for selecting a normal nozzle unit in a first nozzle column;

FIG. 18 is a drawing for explaining an operation of a control unit shown in FIG. 14 when grayscale data 1 is provided to the control unit;

FIG. 19 is a drawing for explaining an operation for selecting a correction nozzle unit in a second nozzle column;

FIG. 20 is a drawing for explaining an operation of the control unit shown in FIG. 14 when grayscale data 4 is provided to the control unit;

FIG. 21 shows, as a table, first correction data and first correction values of a correction parameter;

FIG. 22 shows, as a table, second correction data and second correction values of a correction parameter;

FIG. 23 is a flowchart for explaining an inkjet printing method using an inkjet printing apparatus some embodiments of the present disclosure;

FIG. 24 is a block diagram of an electronic device including a display device including light-emitting elements manufactured by an inkjet printing apparatus some embodiments of the present disclosure; and

FIG. 25 is schematic diagrams of an electronic device some embodiments of the present disclosure.

### DETAILED DESCRIPTION

It will be understood that when an element or layer is referred to as being "on", "connected to" or "coupled to" another element or layer, it can be directly on, connected or coupled to another element or layer or intervening elements or layers may be present.

Like numbers refer to like elements throughout. The thickness and the ratio and the dimension of the element are exaggerated for effective description of the technical contents. As used herein, the term "and/or" includes any and all combinations of one or more of the associated listed items.

It will be understood that, although the terms first, second, etc. may be used herein to describe various elements, these elements, should not be limited by these terms. These terms may be used only to distinguish one component, component, region, layer, or portion from another region, layer, or portion. For example, without departing from the scope of the present invention, the first component, the first part, the first region, the first layer, or the first portion may be named as the second component, the second part, the second region, the second layer, or the second portion, or vice versa. The singular expressions include plural expressions unless the context clearly dictates otherwise.

In addition, terms, such as "beneath", "below", "lower", "above", "upper" and the like, may be used herein to describe the relationship between the components shown in the drawings. The above terms are relative concepts, and are described based on directions indicated in the drawings.

It will be further understood that the terms "comprise" and/or "have", when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of some embodiments of the present disclosure will be explained in more detail with reference to the accompanying drawings.

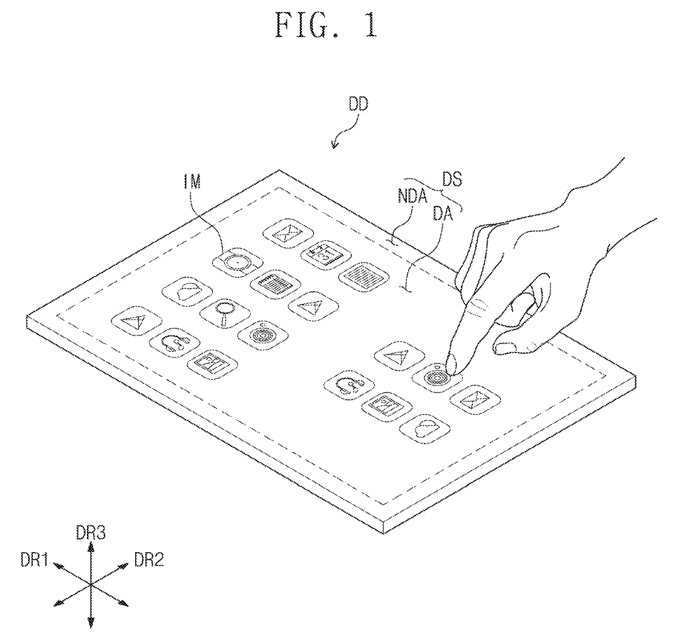

FIG. 1 is a perspective view of a display device including pixels including emission layers manufactured by an inkjet printing apparatus according to some embodiments of the present disclosure.

Referring to FIG. 1, the display device DD according to some embodiments may have a rectangular shape having long sides extending in a first direction DR1, and short sides extending in a second direction DR2 that crosses the first direction DR1. However, embodiments according to the present disclosure are not limited thereto, and the display device DD may have various shapes such as a circular or polygonal shape.

Hereinafter, a normal direction vertical to the plane defined by the first direction DR1 and the second direction DR2 is defined as a third direction DR3. “When viewed in a plan view” disclosed herein may mean a state of being viewed from the third direction DR3.

The top surface of the display device DD may be defined as a display surface DS, and may have a plane defined by the first direction DR1 and the second direction DR2. Images IM generated by the display device DD may be provided to a user through the display surface DS.

The display surface DS may include a display area DA and a non-display area NDA around the display area DA. The display area DA may display images, and the non-display area NDA may not display images. The non-display area NDA may define the outline of the display device DD that surrounds the display area DA and is printed with a prescribed color.

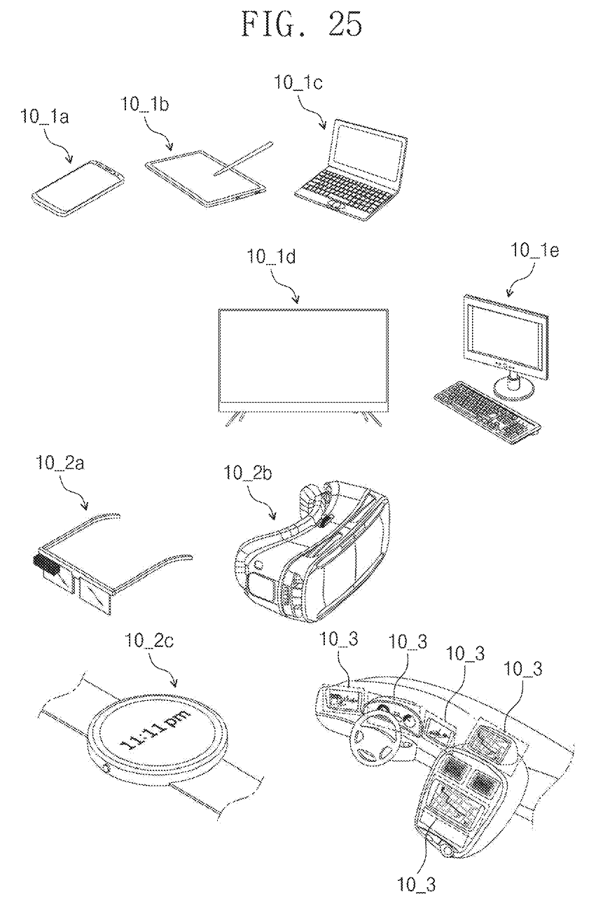

The display device DD may be used in various electronic devices. Examples of the electronic devices in which the display device DD is used will be shown in FIG. 25 below.

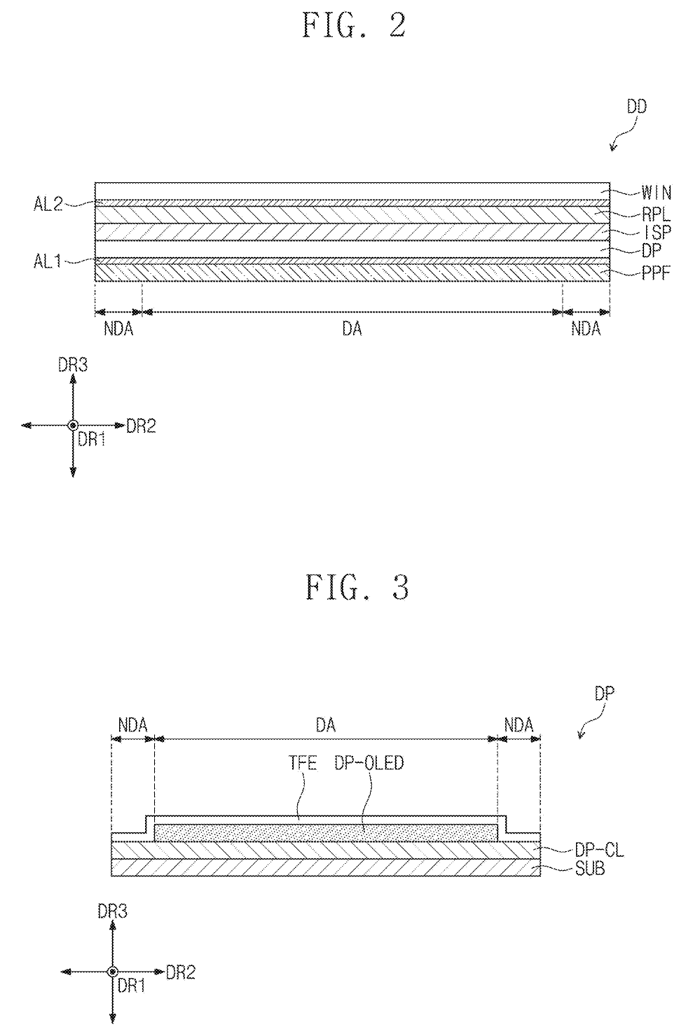

FIG. 2 illustrates an example cross section of the display device shown in FIG. 1.

By way of an example, in FIG. 2, a cross section of the display device DD viewed from the first direction DR1 is shown.

Referring to FIG. 2, the display device DD may include a display panel DP, an input sensing unit ISP, an anti-reflective layer RPL, a window WIN, a panel protection film PPF, and first and second adhesive layers AL and AL2.

The display panel DP according to some embodiments of the present disclosure may be an emissive display panel. For example, the display panel DP may be an organic emissive display panel or an inorganic emissive display panel. An emission layer of the organic emissive display panel may include an organic emissive material. An emission layer of the inorganic emissive display panel may include quantum dots, quantum rods, and the like. Hereinafter, the display panel DP will be described as an organic emissive display panel.

The input sensing unit ISP may be located on the display panel DP. The input sensing unit ISP may include a plurality of sensing units for sensing an external input in a capacitive manner. The input sensing unit ISP may be directly manufactured on the display panel DP in manufacturing the display device DD. However, embodiments according to the present disclosure are not limited thereto, and the sensing unit ISP may be manufactured as a separate panel from the display panel DP to be attached to the display panel DP through an adhesive layer.

The anti-reflective layer RPL may be located on the input sensing unit ISP. The anti-reflective layer RPL may be directly manufactured on the input sensing unit ISP in manufacturing the display device DD. However, embodiments according to the present disclosure are not limited thereto, and the anti-reflective layer RPL may be manufactured as a separate panel to be attached to input sensing unit ISP through an adhesive layer.

The anti-reflective layer RPL may be defined as an incident light anti-reflective film. The anti-reflective layer RPL may relatively reduce a reflectivity of external light incident toward the display panel from the top of the display device DD. The external light may not be visually recognized by users due to the anti-reflective layer RPL.

When the external light traveling toward the display panel DP is reflected by the display panel DP like a mirror and is provided back to the user in the outside, the user may visually recognize the external light. In order to prevent or reduce such a phenomenon, for example, the anti-reflective layer RPL may include a plurality of color filters displaying the same colors as those of the pixels of the display panel DP.

The color filters may filter the external light in the same colors as the pixels. In this case, the external light may not be visually recognized by a user. However, embodiments according to the present disclosure are not limited thereto, and the anti-reflective layer RPL may include a retarder and/or a polarizer configured to relatively reduce the reflectivity of the external light.

The window WIN may be located on the anti-reflective layer RPL. The window WIN may protect the display panel DP, the input sensing unit ISP, and the anti-reflective layer RPL from external scratches or impacts.

The panel protection film PPF may be located under the display panel DP. The panel protection film PPF may protect a lower portion of the display panel DP. The panel protection film PPF may include a flexible plastic material such as polyethyleneterephthalate (PET).

The first adhesive layer AL1 may be located between the display panel DP and the panel protection film PPF, and may bond the display panel DP and the panel protection film PPF. The second adhesive layer AL2 may be located between the window WIN and the anti-protective layer RPL, and may bond the display panel WIN and the anti-protective layer RPL.

FIG. 3 illustrates an example cross section of the display panel shown in FIG. 2.

By way of an example, in FIG. 3, the cross section of the display device DP viewed from the first direction DR1 is shown.

Referring to FIG. 3, the display panel DP may include a substrate SUB, a circuit element layer DP-CL located on the substrate SUB, a display element layer DP-OLED located on the circuit element layer DP-CL, and a thin-film encapsulation layer TFE located on the display element layer DP-OLED.

The substrate SUB may include a display area DA and a non-display area NDA around the display area DA. The substrate SUB may include a flexible plastic material such as polyimide (PI) or glass. The display element layer DP-OLED may be located on the display area DA.

A plurality of pixels may be located in the circuit element layer DP-CL and the display element layer DP-OLED. Each of the pixels may include a transistor located in the circuit element layer DP-CL, and a light-emitting element located in the display element layer DP-OLED to be connected to the transistor.

The thin-film encapsulation layer TFE may be located on the circuit element layer DP-CL so as to cover the display element layer DP-OLED. The thin-film encapsulation layer TFE may protect the pixels from moisture, oxygen, and external foreign matters.

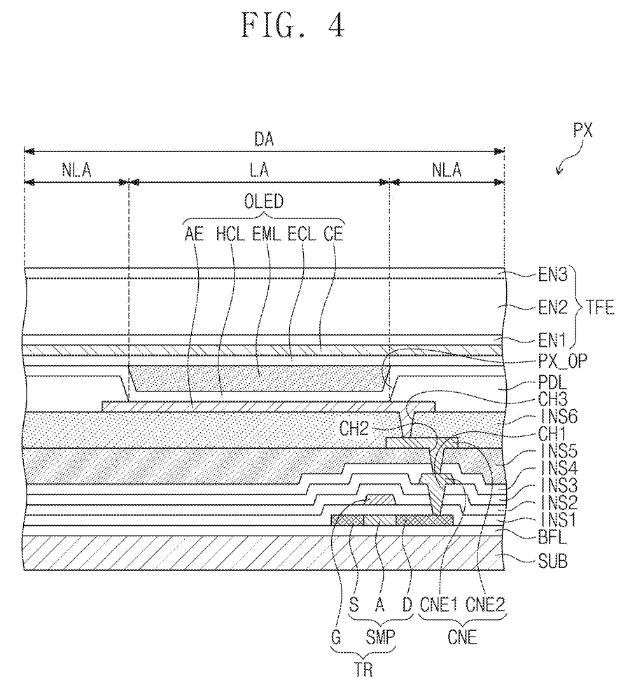

FIG. 4 illustrates an example cross section configuration of any one pixel among the pixels of the display panel shown in FIG. 3.

Referring to FIG. 4, the pixel PX may include the transistor TR and the light-emitting element OLED. The light-emitting element OLED may include a first electrode AE (or an anode), a second electrode CE (or a cathode), a hole control layer HCL, an electron control layer ECL, and an emission layer EML.

The transistor TR and the light-emitting element OLED may be located on the substrate SUB. By way of an example, one transistor TR is shown, but according to various embodiments, the pixel PX may include a plurality of transistors and at least one capacitor for driving the light-emitting element OLED.

The display area DA may include a light-emitting area LA corresponding to each of the pixels PX and a non-light-emitting area NLA around the light-emitting area LA. The light-emitting element OLED may be located in the light-emitting area LA.

A buffer layer BFL may be located on the substrate SUB, and the buffer layer BFL may be an inorganic layer. A semiconductor pattern SMP may be located on the buffer layer BFL. The semiconductor pattern SMP may include polysilicon, amorphous silicon, or a metal oxide.

The semiconductor pattern SMP may be doped with an N-type dopant or a P-type dopant. The semiconductor pattern SMP may include a heavily-doped area and a lightly-doped area. The heavily-doped area may have a larger conductivity than the lightly-doped area, and serve as a source electrode and a drain electrode of the transistor TR. The lightly-doped area may correspond to an active (or channel) of the transistor.

The semiconductor pattern SMP may provide a source S, an active A, and a drain D of the transistor TR. A first insulation layer INS1 may be located on the semiconductor pattern SMP. A gate of the transistor TR may be located on the first insulation layer INS1. A second insulation layer INS2 may be located on the gate G. A third insulation layer INS3 may be located on the second insulation layer INS2.

A connection electrode CNE may include a first connection electrode CNE1 and a second connection electrode CNE2 in order to connect the transistor TR and the light-emitting element OLED. The first connection electrode CNE1 may be located on the third insulation layer INS2 and be connected to the drain D through a first contact hole CH1 defined in the first to third insulation layers INS1 to INS3.

A fourth insulation layer INS4 may be located on the first connection electrode CNE1. A fifth insulation layer INS5 may be located on the fourth insulation layer INS4. The second connection electrode CNE2 may be located on the fifth insulation layer INS5. The second connection electrode CNE2 may be connected to the first connection electrode CNE1 through a second contact hole CH2 defined in the fourth and fifth insulation layers INS4 and INS5. A sixth insulation layer INS6 may be located on the second connection electrode CNE2.

The layers from the buffer layer BFL to the sixth layer INS6 may be defined as the circuit element layer DL-CL. The buffer layer BFL and the first to fourth insulation layers INS1 to INS4 may include inorganic layers. The fifth insulation layer INS5 and the sixth insulation layer INS6 may include organic layers.

The first electrode AE may be located on the sixth insulation layer INS6. The first electrode AE may be connected to the second connection electrode CNE2 through a third contact hole CH3 defined in the sixth insulation layers NS6. A pixel definition layer PDL in which an opening PX_OP for exposing a prescribed portion of the first electrode AE is defined may be located on the first electrode AE and the sixth insulation layer INS6.

The hole control layer HCL may be located on the first electrode AE and the pixel definition layer PDL. The hole control layer HCL may include a hole transport layer and a hole injection layer.

The emission layer EML may be located on the hole control layer HCL. The emission layer EML may be located in an area corresponding to the opening PX_OP. The emission layer EML may include an organic material and/or an inorganic material. The emission layer EML may generate light of any one of red, green, or blue color.

The electron control layer ECL may be located on the emission layer EML and the hole control layer HCL. The electron control layer ECL may include an electron transport layer and an electron injection layer. The hole control layer HCL and the electron control layer ECL may be commonly located in the light-emitting area LA and the non-light-emitting area NLA.

The second electrode CE may be located on the electron control layer ECL. The second electrode CE may be commonly located in the pixels PX. The layer on which the light-emitting element OLED is located may be defined as the display element layer DP-OLED.

The thin-film encapsulation layer TFE may be located on the second electrode CE to cover the pixel PX. The thin-film encapsulation layer TFE may include a first encapsulation layer EN1, a second encapsulation layer EN2 located on the first encapsulation layer EN1, a third encapsulation layer EN3 located on the second encapsulation layer EN2.

The first and third encapsulation layers EN1 and EN3 may include inorganic insulation layers and protect the pixel PX from moisture/oxygen. The second encapsulation layer EN2 may include an organic insulation layer and protect the pixel PX from foreign matters such as dust particles.

A first voltage may be applied to the first electrode AE through the transistor TR, and a second voltage having a lower level than the first voltage may be applied to the second electrode CE. Holes and electrons injected to the emission layer EML may be combined to form excitons, and the light-emitting element OLED may emit light while the excitons are transitioned to the ground state.

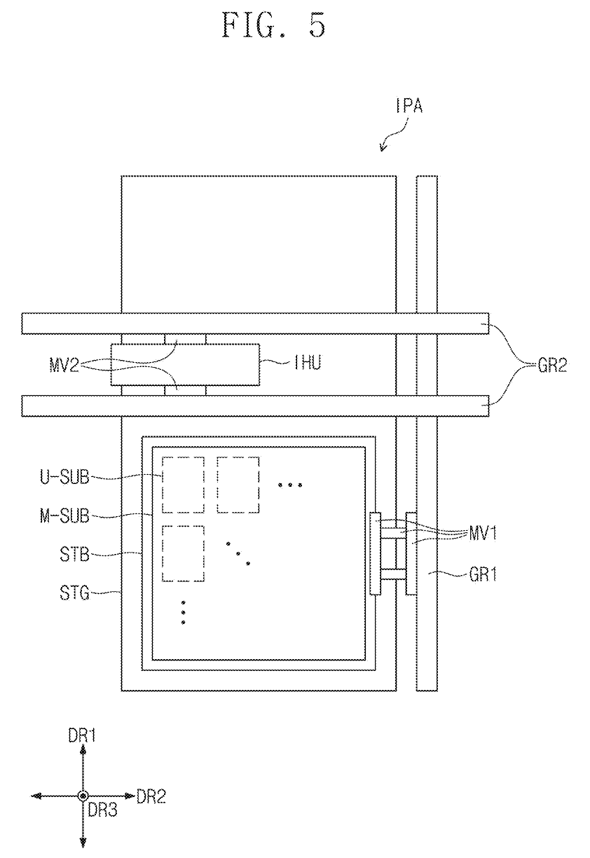

FIG. 5 shows the configuration of an inkjet printing apparatus according to some embodiments of the present disclosure.

By way of an example, in FIG. 5, a planar configuration of the inkjet printing apparatus IPA viewed from the third direction DR3 (e.g., in a plan view) is shown.

Referring to FIG. 5, the inkjet printing apparatus IPA may include a stage STG, a support table STB, a first moving unit MV1, a first guide rail GR1, a second moving unit MV2, a plurality of second guide rails GR2, and an inkjet head unit IHU.

The stage STG may have a rectangular shape with long sides extending in the first direction DR1 and short sides extending in the second direction DR2. The support table STB may be located on the stage STG, and a mother substrate M-SUB, which is a substrate to be processed, may be located on the support table STB.

The mother substrate M-SUB may include a plurality of unit substrates U-SUB. Each of the unit substrates U-SUB may correspond to the display device DD shown in FIG. 1. Each of the unit substrates U-SUB may correspond to the substrate SUB shown in FIG. 3. Pixels may be provided on each of the unit substrates SUB to allow the display device DD to be manufactured.

The first guide rail GR1 may be adjacent to one of both sides of the stage STG, the both sides being opposite to each other in the second direction DR2. The first guide rail GR1 may extend in the first direction DR1.

The first moving unit MV1 may be connected to one side of the support table STB adjacent to one side of the stage STG. The first moving unit MV1 may be connected to the first guide rail GR1. The first moving unit MV1 may move along the first guide rail GR1 in the first direction DR1. According to the movement of the first moving unit MV1, the support table STB connected to the first moving unit MV1 may move in the first direction DR1. Accordingly, the mother substrate M-SUB located on the support table STB may move in the first direction DR1.

The second guide rails GR2 may be located on the state STG to extend in the second direction DR2. By way of an example, one pair of the second guide rails GR2 may be located on the stage STG. The second guide rails GRb may be located on the mother stage M-SUB. The second guide rails GR2 may be spaced apart from each other in the first direction DR1.

The inkjet head unit IHU may be located between the second guide rails GR2. The inkjet head but IHU may extend longer in the second direction DR2 than in the first direction DR1. The second moving unit MV2 may be connected to the inkjet head unit IHU and the second guide rails GR2. The inkjet head unit IHU may be connected to the second guide rails GR2 through the second moving unit MV2.

The second moving unit MV2 may move along the second guide rails GR2 in the second direction DR2. According to the movement of the second moving unit MVb, the inkjet head unit IHU connected to the second moving unit MVb may move in the second direction DR2.

The mother substrate M-SUB may move in the first direction DR1 to be located under the inkjet head unit IHU. The inkjet head unit IHU located on the mother-substrate M-SUB may discharge the ink onto the unit substrates U-SUB while moving in the second direction DR2. According to that the inkjet head unit IHU discharges the ink onto the unit substrates U-SUB, the emission layers EML of the pixels PX may be provided.

By way of an example, one inkjet head unit IHU is shown, but the inkjet printing apparatus IPA may include a plurality of head units IHU. For example, the pixels PX may include red pixels configured to emit red light, green pixels configured to emit green light, and blue pixels configured to emit green light.

The inkjet head units IHU may include a first inkjet head unit for providing emission layers of the red pixels, a second inkjet head unit for providing emission layers of the green pixels, and a third inkjet head unit for providing emission layers of the blue pixels. The first, second, and third inkjet head units may move in the second direction DR2 through the corresponding second guide rails GR2 and the corresponding second moving units MV2.

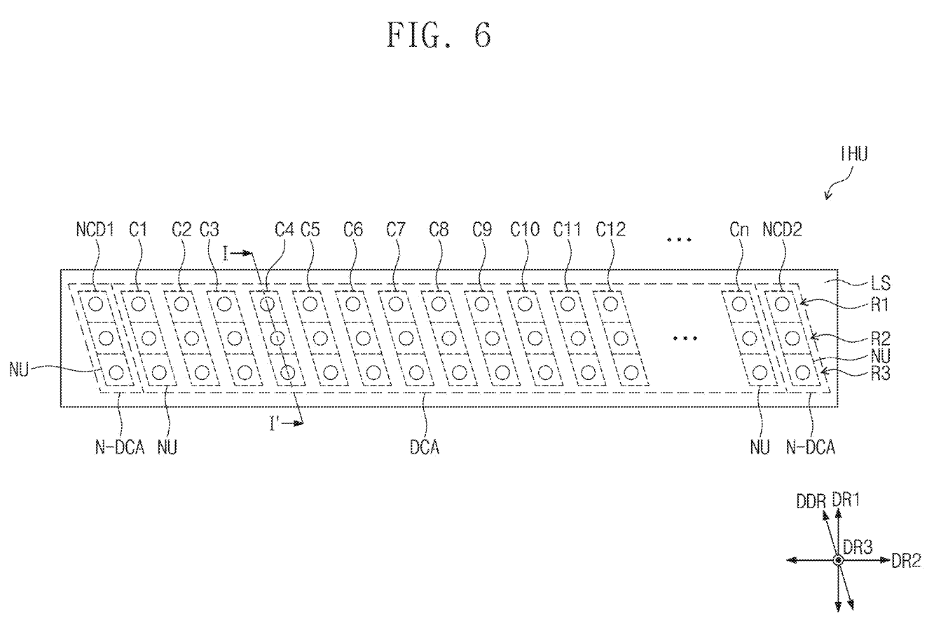

FIG. 6 shows the configuration of the inkjet head unit shown in FIG. 5.

By way of an example, FIG. 6 shows a lower surface LS of the inkjet head unit IHU viewed from the third direction DR3.

Referring to FIG. 6, the inkjet head unit IHU may include a plurality of nozzle units NU. The plurality of nozzle units NU may be arranged into a plurality of rows R1, R2, and R3, and a plurality of columns NDC1, C1 to Cn, and NDC2.

The rows R1, R2, and R3 may correspond to the second direction DR2. By way of an example, the nozzle units NU may be arranged into a first row R1, a second row R2, and a third row R3.

The columns NDC1, C1 to Cn, and NDC2 may correspond to a diagonal direction DDR. The diagonal direction DDR may cross the first and second directions DR1 and DR2. The diagonal direction DDR may extend to form an acute angle with the first direction DR1.

A plurality of nozzle units NU may be located in each of the columns NDC1, C1 to Cn, and NDC2. The nozzle units NU may be located in the diagonal direction DDR in each of the columns NDC1, C1 to Cn, and NDC2.

The nozzle units NU are shown in the diagonal direction DDR by way of an example, but the embodiments of the present disclosure may not be limited thereto. For example, the columns NDC1, C1 to Cn, and NDC2 may correspond to the first direction DR1, and the nozzle units NU may be located in the first direction DR1 in each of the columns NDC1, C1 to Cn, and NDC2.

A discharge area DCA and non-discharge areas N-DCA may be defined in a lower surface LS of the inkjet head unit IHU. The non-discharge areas N-DCA may be adjacent to both sides of the lower surface LS opposite to each other in the second direction DR2. The discharge area DCA may be arranged between the non-discharge areas N-DCA.

The columns NDC1, C1 to Cn, and NDC2 may include a plurality of first to n-th nozzle columns C1 to Cn, a first non-discharge nozzle column NDC1, and a second non-discharge nozzle column NDC2. The first to n-th nozzle columns C1 to Cn may be arranged in the discharge area DCA. The first non-discharge nozzle column NDC1 and the second non-discharge nozzle column NDC2 may be arranged in the non-discharge areas N-DCA, respectively. Accordingly, the first to n-th nozzle columns C1 to Cn may be arranged between the first non-discharge nozzle column NDC1 and the second non-discharge nozzle column NDC2.

The first and second non-discharge nozzle columns NDC1 and NDC2 may be arranged adjacent to both sides of the inkjet head unit IHU, respectively. Specifically, the first non-discharge nozzle column NDC1 may be located in the non-discharge area N-DCA adjacent to one side between both sides of the lower surface LS opposite to each other in the second direction DR2. The second non-discharge nozzle column NDC2 may be located in the non-discharge area N-DCA adjacent to the other side between the both sides of the lower surface LS opposite to each other in the second direction DR2.

Nozzle holes NH may be defined in the nozzle units NU, respectively. The nozzle holes NH may be defined on the lower surface LS.

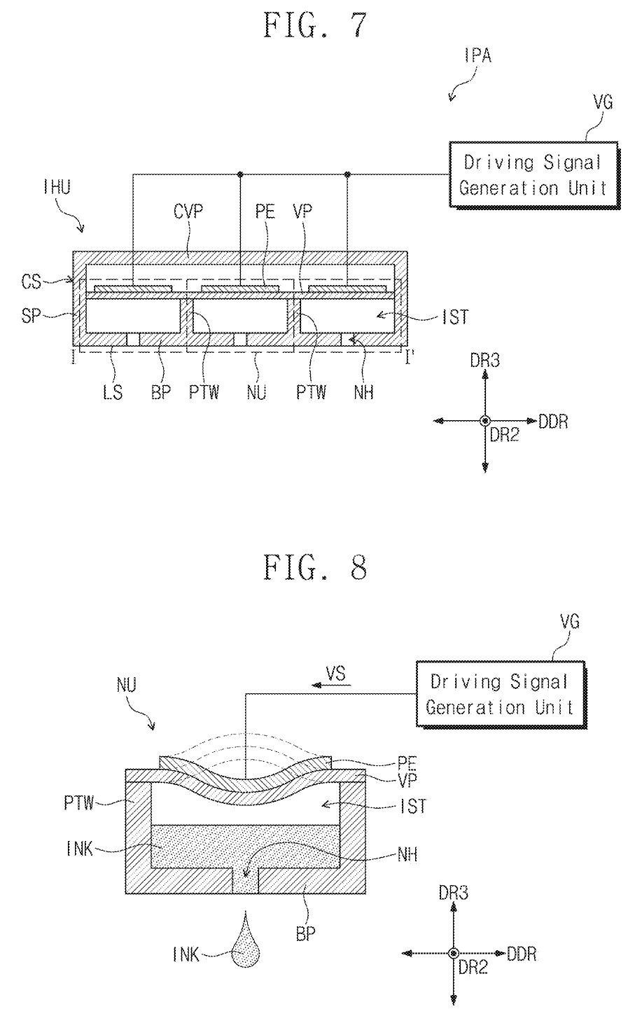

FIG. 7 is a cross-sectional view cut along line I-I’ shown in FIG. 6.

Referring to FIG. 7, the inkjet head unit IHU may include a case CS, a plurality of piezoelectric elements PE, and a vibration plate VP. The piezoelectric elements PE and the vibration plate VP may be housed in the case CS.

The case CS may include a bottom part BP, a plurality of side wall parts SP, and a cover part CVP. The bottom part BP and the cover part CVP may have planes defined by the first and second directions DR1 and DR2. The side wall parts SP may extend in the third direction DR3. The side wall parts SP may extend upward from ends of the bottom unit BP. The cover part CVP may extend from the top of the bottom part BP. The bottom part BP, the side wall parts SP, and the cover part CVP may be integrally provided.

The lower surface LS shown in FIG. 6 may be defined on the bottom part BP. A plurality of nozzle holes NH may be defined which penetrate through the bottom part BP in the third direction DR3.

The case CS may include a plurality of partition walls PTW protruding upward in portions of the bottom part BP. The partition walls PTW may be arranged between the side wall parts SP. Spaces between the adjacent partition walls PTW and spaces between the adjacent partition walls PTW and the side wall parts SP may be defined as ink storage tanks IST. The bottom part BP may define the bottom of the ink storage tanks IST. Namely, the ink storage tanks IST may be defined by the bottom part BP, the partition walls PTW, and the side wall parts SP.

The nozzle holes NH may be defined to respectively correspond to the ink storage tanks IST. The nozzle holes NH may respectively overlap the ink storage tanks IST. Each of the nozzle holes NH may be continuously defined in the corresponding ink storage tank IST among the ink storage tanks IST.

The vibration plate VP may be located on the partition walls PTW. The vibration plate VP may cover the ink storage tanks IST. The volume of the ink storage tanks IST may be defined by the vibration plate VP. The top portions of the ink storage tanks IST may be closed by the vibration plate VP. The vibration plate VP may include a metal and be provided on the partition walls PTW in a thin plate shape. The vibration plate VP may be elastic and vibrate in the third direction DR3.

The piezoelectric elements PE may be located on the vibration plate VP. The piezoelectric elements PE may be a laminated piezo actuator. The piezoelectric elements PE may be respectively located on the ink storage tanks IST.

The nozzle units NU may be defined as portions of the inkjet head unit IHU segmented by the partition walls PTW. Each of the nozzle units NU may include a portion of the case CS defining each of the ink storage tanks IST, a portion of the vibration plate VP overlapping each of the ink storage tanks IST, and the piezoelectric element PE on each of the ink storage tanks IST. The portions of the case CS defining the ink storage tanks IST may be defined by the portions of the bottom part BP, the side wall parts SP, and the partition walls PTW.

The portions of the bottom part BP defining the ink storage tanks IST may be defined as a portion of the bottom part BP between the adjacent partition walls PTW and a portion of the bottom part BP between partition wall PTW and side wall SP that are adjacent to each other. Accordingly, the nozzle hole NH may be defined in the bottom part BP of each of the nozzle units NU.

According to some embodiments, the ink storage tanks IST may be connected to an ink supply part to be provided with ink from the ink supply part.

The inkjet printing apparatus IPA may include a driving signal generation unit VG. The driving signal generation unit VG may be connected to the piezoelectric elements PE. The driving signal generation unit VG may generate a driving signal. The driving signal generation unit VG may include a driving circuit for generating the driving signal.

Grayscale data may be applied to the inkjet head unit IHU. The grayscale data will be specifically described below. According to the grayscale data applied to the inkjet head unit IHU, any one of the nozzle units NU of the discharge area DCA may be selected. The driving signal may be applied to the piezoelectric element PE of the selected nozzle unit NU. The piezoelectric element PE of the selected nozzle unit NU may vibrate the vibration plate VP of the selected nozzle unit NU. The configuration in which the nozzle unit NU is selected and the driving signal is applied to the selected nozzle unit will be specifically described below.

According to some embodiments of the present disclosure, a plurality of driving signal generation units are not respectively connected to the nozzle units NU, but a single driving signal generation unit VG may be commonly connected to the nozzle units NU. Accordingly, the configuration of the inkjet printing apparatus IPA may be simplified.

FIG. 8 shows any one nozzle unit shown in FIG. 7.

In FIG. 8, it is shown that an example nozzle unit NU is located at the center of the nozzle units NU shown in FIG. 7. The nozzle unit NU shown in FIG. 8 may be defined as a nozzle unit NU selected with the grayscale data.

Referring to FIG. 8, the ink storage tank IST may be filled with ink INK. The driving signal generation unit VG may generate the driving signal VS and the generated driving signal VS may be applied to the piezoelectric element PE of the nozzle unit NU. The piezoelectric element PE to which the driving signal VS is applied may vibrate the vibration plate VP in a vertical direction. According to the vibration of the vibration plate VP, the ink storage tank IST may be expanded or contracted.

When the vibration plate VP moves upward, the ink storage tank IST is expanded to relatively reduce the pressure in the ink storage tank IST. When the vibration plate VP moves downward, the ink storage tank IST is contracted to increase the pressure in the ink storage tank IST. When the pressure in the ink storage tank IST increases, the ink INK may be discharged through the nozzle hole NH.

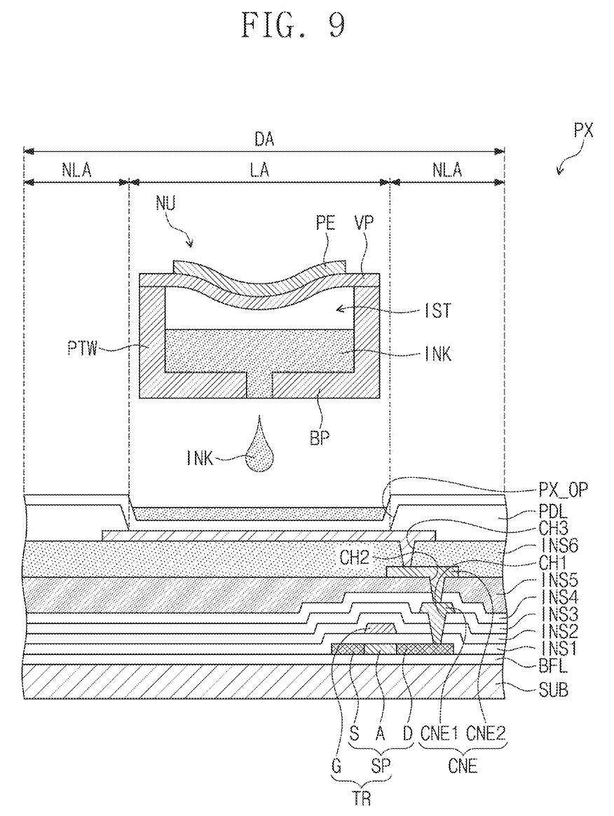

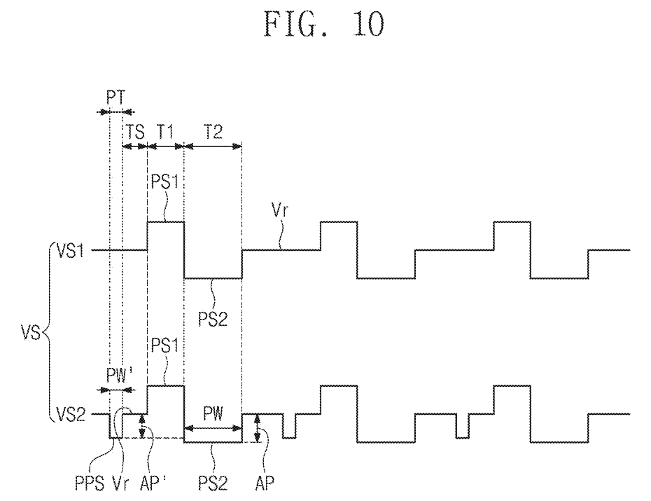

FIG. 9 is a drawing for explaining a process in which the ink is provided to a light-emitting area through the nozzle unit shown in FIG. 8.

Referring to FIGS. 4 and 9, the emission layer EML of the light-emitting element OLED may be provided in the light-emitting area LA. In order to provide the emission layer EML, the nozzle unit NU may move onto the light-emitting area LA. When the pressure in the ink storage tank IST increases, the ink INK may be discharged to the light-emitting area LA through the nozzle hole NH.

A target ink amount for forming the light-emitting layer EML may be set. The ink INK may be discharged to the light-emitting area LA a plurality of times in order to provide the ink to the light-emitting area LA as much as the target amount.

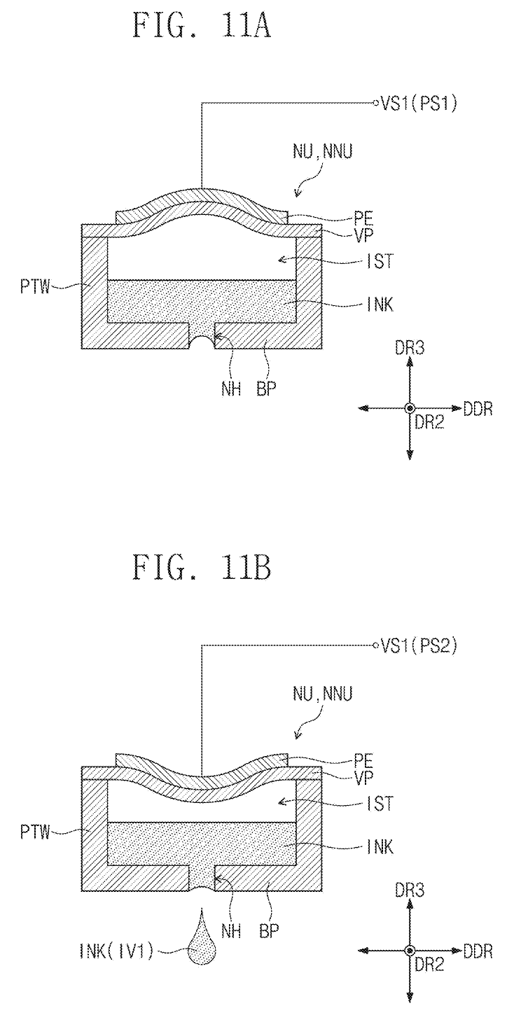

FIG. 10 shows waveforms of the driving signals generated by the driving signal generation unit shown in FIGS. 7 and 8.

Referring to FIG. 10, the driving signals VS generated by the driving signal generation unit VG may include a first driving signal VS1 and a second driving signal VS2. The first driving signal VS1 and the second driving signal VS2 may be defined as a driving voltage, a discharge control signal, or the like.

The first driving signal VS1 may include successive first and second pulses PS1 and PS2. The first pulse PS1 may have a higher level than a reference voltage Vr during a first period T1. The second pulse PS2 may have a lower level than the reference voltage Vr during a second period T2. The second period T2 may directly follow the first period T1. Accordingly, the second pulse PS2 may be generated successively to the first pulse PS1.

The second driving signal VS2 may include successive preliminary, first, and second pulses PPS, PS1, and PS2. The preliminary pulse PPS may have a lower level than the reference voltage Vr during a preliminary period PT. The first pulse PS1 may have a higher level than the reference voltage Vr during a first period T1 following the preliminary period PT. The second pulse PS2 may have a lower level than the reference voltage Vr during a second period T2 following the first period T1. The first pulse PS1 and the second pulse PS2 of the second driving signal VS2 may be the same (or substantially the same) as the first pulse PS1 and the second pulse PS2 of the first driving signal VS1.

The period between the preliminary period PT and the first period T1 may be defined as a timing shift period TS. Although the second period T2 may directly follow the first period T1, the first period T1 may follow the timing shift period TS following the preliminary period PT. Accordingly, after the preliminary pulse PPS is generated and the timing shift period TS passes, the first pulse PS1 may be generated. During the timing shift period TS, the second driving signal VS2 may have the level of the reference voltage Vr.

A pulse application period may be defined as a pulse width. The width PW’ of the preliminary pulse PPS may be smaller than the width PW of the second pulse PS2. The amplitude AP’ of the preliminary pulse PPS may be smaller than the amplitude AP of the second pulse PS2.

The first driving signal VS1 may be applied to a nozzle selected according to the grayscale data. The second driving signal VS2 may be applied to another nozzle selected according to the grayscale data. These operations will be described below.

FIGS. 11A and 11B are drawings for explaining the operation of a nozzle unit to which the first driving signal is applied.

Hereinafter, the nozzle unit NU shown in FIGS. 11A and 11B may be defined as a normal nozzle unit NNU.

Referring to FIGS. 10 and 11A, the first pulse PS1 of the first driving signal VS1 may be applied to a piezoelectric element PE of the normal nozzle unit NNU. When the first pulse PS1 having a higher level than the reference voltage Vr is applied to the piezoelectric element PE, the vibration plate VP may move upward due to the piezoelectric element PE. Accordingly, the ink storage tank IST may be expanded to relatively reduce the pressure of the ink storage tank IST. As a result, the ink INK may not be discharged through the nozzle hole NH.

Referring to FIGS. 10 and 11B, the second pulse PS2 of the first driving signal VS1 may be applied to the piezoelectric element PE of the normal nozzle unit NNU. When the second pulse PS2 having a lower level than the reference voltage Vr is applied to the piezoelectric element PE, the vibration plate VP may move downward by the piezoelectric element PE. Accordingly, the ink storage tank IST may be contracted to increase the pressure of the ink storage tank IST. As a result, the ink INK may be discharged through the nozzle hole NH. The ink INK discharged according to the first driving signal VS1 may have a first ink amount IV1.

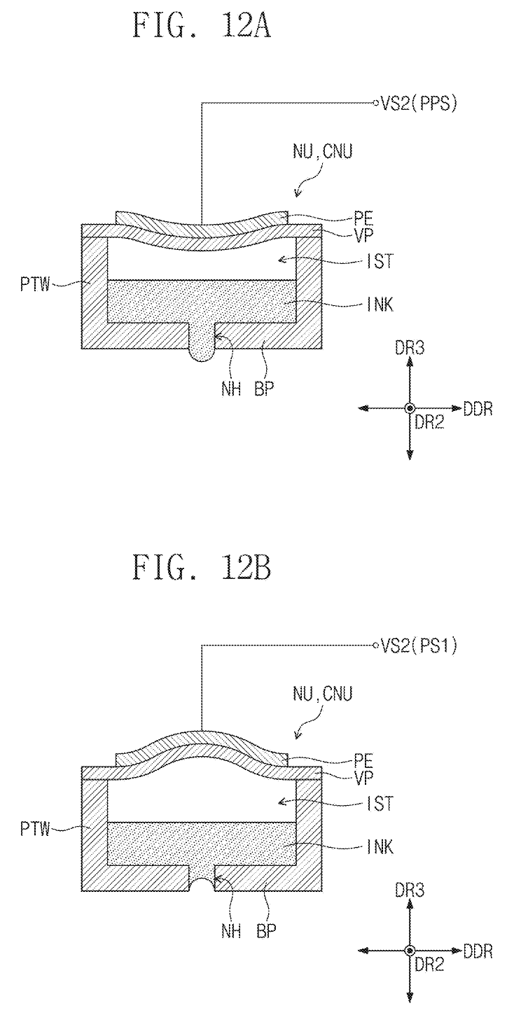

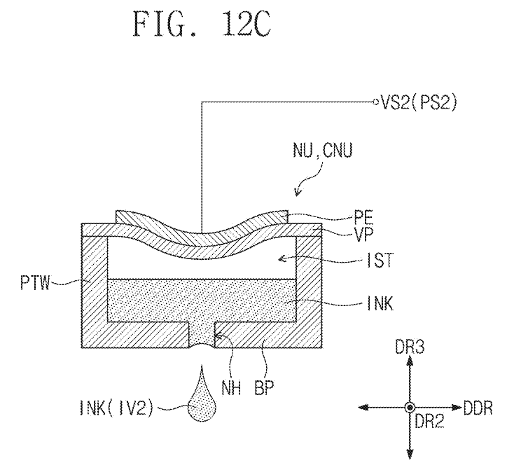

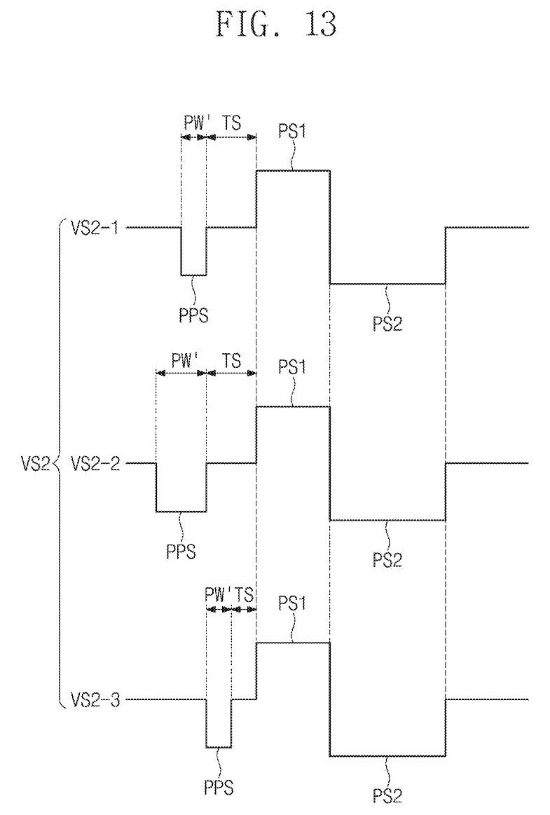

FIGS. 12A to 12C are drawings for explaining the operation of a nozzle unit to which the second driving signal is applied.

Hereinafter, the nozzle unit NU shown in FIGS. 12A to 12C may be defined as a correction nozzle unit CNU.

Referring to FIGS. 10 and 12A, the preliminary pulse PPS of the second driving signal VS2 may be applied to a piezoelectric element PE of the correction nozzle unit CNU. When the preliminary pulse PPS having a lower level than the reference voltage Vr is applied to the piezoelectric element PE, the vibration plate VP may move downward. Accordingly, the ink storage tank IST may be contracted to increase the pressure of the ink storage tank IST.

The pressure of the ink storage tank IST according to the preliminary pulse PPS may not be sufficient to discharge the ink. Accordingly, the ink INK may not be discharged through the nozzle hole NH. The ink INK may have a shape protruding downward according to a meniscus phenomenon in the nozzle hole NH. As a result, when the preliminary pulse PPS is applied to the correction nozzle unit CNU, the correction nozzle unit CNU may not discharge the ink INK.

Referring to FIGS. 10 and 12B, the first pulse PS1 of the first driving signal VS2 may be applied to the piezoelectric element PE of the correction nozzle unit CNU. Like the operation of FIG. 11A, the ink storage tank IST may be expanded to relatively reduce the pressure of the ink storage tank IST, and the ink INK may not be discharged through the nozzle hole NH.

Referring to FIGS. 10 and 12C, the second pulse PS2 of the second driving signal VS2 may be applied to the piezoelectric element PE of the correction nozzle unit CNU. Like the operation of FIG. 11B, the ink storage tank IST may be contracted to increase the pressure of the ink storage tank IST, and the ink NH may be discharged through the nozzle hole NH. When the second pulse PSb is applied to the correction nozzle unit CNU, the correction nozzle unit CNU may discharge the ink INK. The ink INK discharged in response to the second driving signal VS2 may have a second ink amount IV2 different from the first ink amount IV1.

The ink amount discharged according to the vibration of the first pulse PS1 and the second pulse PS2 of the first driving signal VS1 may be less than that discharged according to the vibration of the preliminary pulse PPS, the first pulse PS1, and the second pulse PS2 of the second driving signal VS2. When pre-vibration is generated by the preliminary pulse PPS, the amount of discharged ink may increase. Accordingly, the second ink amount IV2 may be more than the first ink amount IV1.

FIG. 13 illustrates various example waveforms of the second driving signal shown in FIG. 10.

Referring to FIG. 13, the width PW’ of the preliminary pulse PPS and the timing shift period TS may be variously set in the second driving signal VS2. The second driving signal VS2 may include a (2-1)-th driving signal VS2-1, a (2-2)-th driving signal VS2-2, and a (2-3)-th driving signal VS2-3.

The width PW’ of a preliminary pulse PPS2-2 of the (2-2)-th driving signal VS2-2 may be greater than the width PW’ of a preliminary pulse PPS of the (2-1)-th driving signal VS2-1. In this case, the second ink amount IV2 discharged from the correction nozzle unit CNU may be more when applying the (2-2)-th driving signal VS2-2 to the correction nozzle unit CNU than when applying the (2-1)-th driving signal VS2-1 to the correction nozzle unit CNU.

The timing shift period TS of the (2-3)-th driving signal VS2-3 may be smaller than that of the (2-1)-th driving signal VS2-1. Accordingly, in the (2-3)-th driving signal VS2-3 other than the (2-1)-th driving signal VS2-1, a time interval between the preliminary pulse PPS and the first pulse PS1 may be shortened. Namely, the preliminary pulse PPS and the first pulse PS1 may vibrate faster. In this case, the second ink amount IV2 discharged from the correction nozzle unit CNU may be more when applying the (2-3)-th driving signal VS2-3 to the correction nozzle unit CNU than when applying the (2-1)-th driving signal VS2-1 to the correction nozzle unit CNU.

According to some embodiments of the present disclosure, the width PW’ of the preliminary pulse PPS and the timing shift period CNU may be variously set, and thus the second ink amount IV2 discharged from the correction nozzle unit CNU may be changed in various ways.

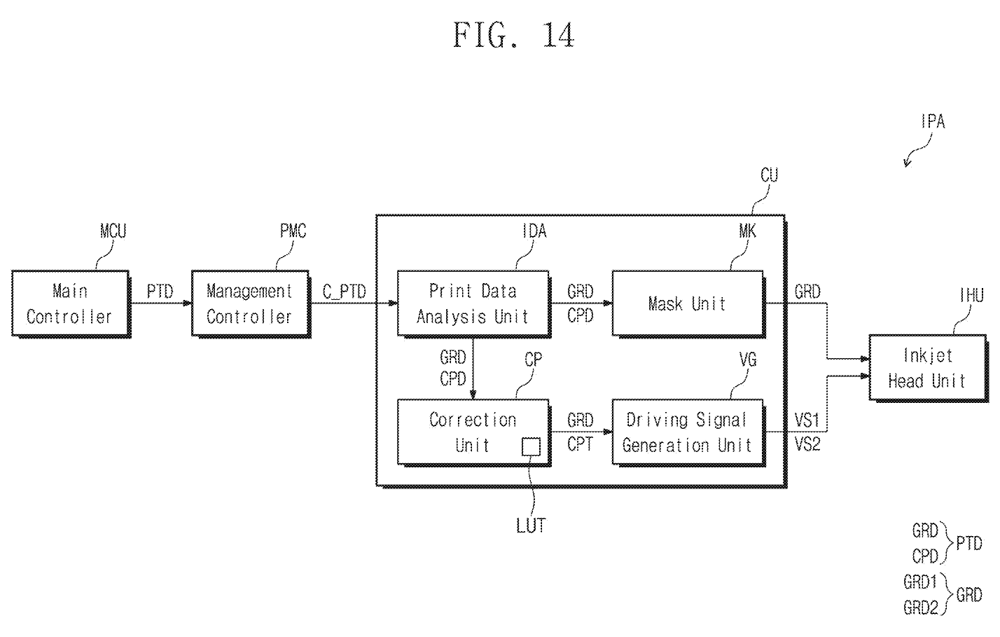

FIG. 14 is a block diagram of an inkjet printing apparatus according to some embodiments of the present disclosure.

Referring to FIG. 14, the inkjet printing apparatus IPA may include a main controller MCU, a management controller PMC, a control unit CU, and an inkjet head unit IHU.

The main controller MCU may provide print data PTD to the management controller PMC. The print data PTD may include grayscale data and correction data CPD. The management controller PMC may compress the print data PTD, and provide the compressed print data C_PTD to the control unit CU.

The control unit CU may analyze the compressed print data C_PTD to select a nozzle unit NU of the inkjet head unit IHU and apply a driving signal VS to the selected nozzle nit NU. For these operations, the control unit CU may include a print data analysis unit IDA, a mask unit MK, a correction unit CP, and a driving signal generation unit VG.

The print data analysis unit IDA may receive and analyze the compressed print data C_PTD. For example, the print data analysis unit IDA may decompress the compressed print data C_PTD to output the print data PTD. The print data analysis unit IDA may provide the grayscale data and the correction data CPD of the print data PTD to the mask unit MK and the correction unit CP.

The print data PTD may be defined as data corresponding to the nozzle units LU. For example, when the nozzle units LU are arranged into the first row R1, the second row R2, and the third row R3 as shown in FIG. 6, the print data PTD may be defined as 3-bit data.

The grayscale data GRD may be provided to the inkjet head unit IHU through the mask unit MK. The correction data CPD may be masked, namely, removed in the mask unit MK and not be provided to the inkjet head unit IHU.

When the grayscale data GRD is provided to the inkjet head unit IHU, a nozzle unit NU corresponding to the grayscale data GRD may be selected from among the nozzle units LU of the first to n-th nozzle columns C1 to Cn. The selected nozzle unit NU may discharge the ink INK.

The grayscale data GRD may include first grayscale data GRD1 and second grayscale data GRD2. When the first grayscale data GRD1 is provided to the inkjet head unit IHU, a nozzle unit NNU corresponding to the first grayscale data GRD may be selected as the above-described normal nozzle unit NNU. When the second grayscale data GRD2 is provided to the inkjet head unit IHU, a nozzle unit CNU corresponding to the second grayscale data GRD may be selected as the above-described correction nozzle unit CNU.

The correction data CPD is data that may be provided to first and second non-discharge nozzle columns NDC1, but may be removed (or substantially removed) in the mask unit MK and not be provided to the first and second non-discharge nozzle columns NDC1. The correction data CPD may be used to generate the second driving signal VS2, and thus may not be provided to the inkjet head unit IHU.

If the correction data CPD is provided to the inkjet head unit IHU, the ink INK may be discharged from the nozzle unit NU selected from among the first and second non-discharge nozzle columns NDC1. The correction data CPD may be removed in the mask unit MK so that the ink is not discharged from the first and second non-discharge nozzle columns NDC1.

The grayscale data GRD may be provided to the driving signal generation unit VG through the correction unit CP. The correction unit CP may include a lookup table LUT, and a correction parameter CPT may be stored in the lookup table LUT. The correction unit CP may provide the correction parameter CPT corresponding to the correction data CPD to the driving signal generation unit.

The driving signal generation unit VG may generate the above-described first driving signal VS1 in response to the first grayscale data GRD1. The driving signal generation unit VG may generate the above-described second driving signal VS2 in response to the second grayscale data GRD2 and the correction parameter CPT. The first driving signal VS1 and the second driving signal VS2 may be provided to the inkjet head unit IHU.

The first driving signal VS1 is applied to the normal nozzle unit NNU selected with the first grayscale data GRD1, and the normal nozzle unit NNU may discharge the ink INK. The second driving signal VS2 is applied to the correction nozzle unit CNU selected with the second grayscale data GRD2, and the correction nozzle unit CNU may discharge the ink INK.

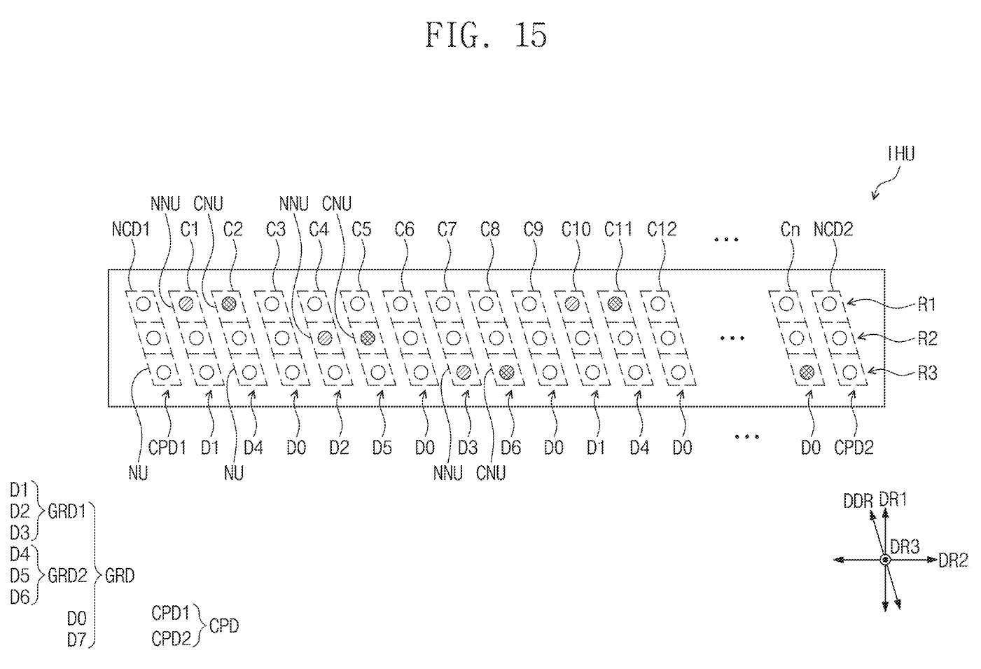

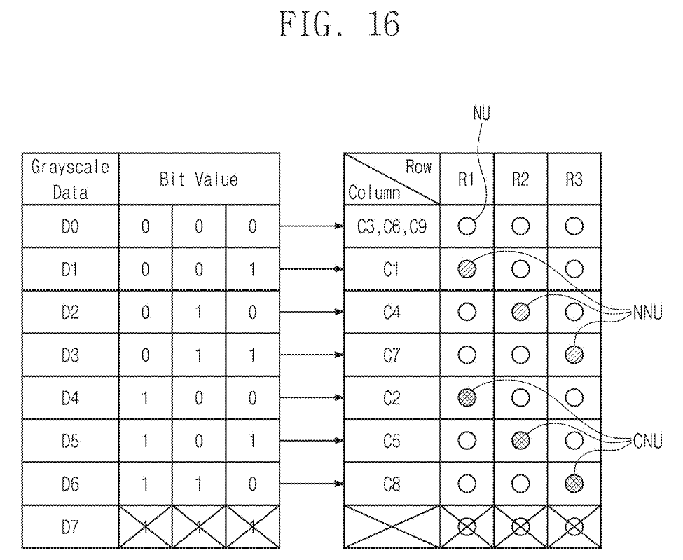

FIG. 15 shows nozzle units that may be selected according to the grayscale data able to be provided to the first to n-th nozzle columns. FIG. 16 shows, as a table, the nozzle units that may be selected according to the grayscale data.

Referring to FIGS. 15 and 16, the grayscale data GRD may include grayscale data 0 to 7 D0 to D7 as 3-bit data corresponding to the first, second, and third rows R1, R2, and R3. The grayscale data 0 to 7 D0 to D7 may be respectively defined as pieces of 3-bit data of "000", "001", "010", "011", "100", "101", "110", and "111”.

The first grayscale data GRDb may include the grayscale data 1 D1, grayscale data 2 D2, and grayscale data 3 D3. The second grayscale data GRD2 may include grayscale data 4 D4, grayscale data 5 D5, and grayscale data 6 D6. According to some embodiments of the present disclosure, grayscale data 7 D7 may not be used. By way of an example, a portion of the table corresponding to grayscale data 7 D7, which is not used, is indicated as “X” in FIG. 16.

Hereinafter, example operations of the first to ninth nozzle columns C1 to C9 will be described.

The first grayscale data GRD1 may be provided to the first nozzle column C1, the fourth nozzle column C4, and the seventh nozzle column C7. The second grayscale data GRD2 may be provided to the second nozzle column C2, the fifth nozzle column C5, and the eighth nozzle column C8. Grayscale data D0 may be provided to the third nozzle column C3, the sixth nozzle column C6, and the ninth nozzle column C9.

In the following order, grayscale data 0 to 6 D0 to D6 may be provided to the first to ninth nozzle columns C1 to C9.

Grayscale data 1 D1 may be provided to the first nozzle column C1, grayscale data 4 D4 may be provided to the second nozzle column C2, grayscale data 0 D0 may be provided to the third nozzle column C3, grayscale data 2 D2 may be provided to the fourth nozzle column C4, grayscale data 5 D5 may be provided to the fifth nozzle column C5, grayscale data 0 D0 may be provided to the sixth nozzle column C6, grayscale data 3 D3 may be provided to the seventh nozzle column C7, grayscale data 6 D6 may be provided to the eighth nozzle column C8, and grayscale data 0 D0 may be provided to the ninth nozzle column C9. Grayscale data 0 to 6 D0 to D6 may be provided to next nozzles in that order.

That order is shown as an example, and the order in which grayscale data 0 to 6 D0 to D6 are applied to the first to ninth nozzle columns C1 to C9 may be set in various ways.

The correction data CPD may include first correction data CPD1 and second correction data CPD2. The first correction data CPD1 may be 3-bit data corresponding to the first non-discharge nozzle column NDC1, and the second correction data CPD2 may be 3-bit data corresponding to the second non-discharge correction column NCD2.

However, as the described above, the first and second correction data CPD1 and CPD2 may not be provided to the first and second non-discharge nozzle columns NDC1 and NDC2. Accordingly, nozzle units NU of the first and second non-discharge nozzle columns NDC1 and NDC2 may not discharge the ink.

Grayscale data 0 D0 is applied to the third, sixth, and ninth nozzle columns C3, C6, and C9, and the nozzle units NU of the third, sixth, and ninth nozzle columns C3, C6, and C9 may not be selected. In this case, the nozzle units NU of the third, sixth, and ninth nozzle columns C3, C6, and C9 may be in an inactive state in which the ink INK is not discharged.

When grayscale data 1 D1 is provided to the first nozzle column C1, the nozzle unit NU of the first nozzle column C1 and the first row R1 may be selected. The selected nozzle unit NU of the first nozzle column C1 may be activated to a discharge state in which the ink may be discharged. The nozzle unit NU of the first nozzle column C1 and the first row R1 may be defined as the foregoing normal nozzle unit NNU. In this case, the first driving signal VS1 may be applied to the selected nozzle unit NU of the first nozzle column C1.

When grayscale data 2 D2 is provided to the fourth nozzle column C4, the nozzle unit NU of the fourth nozzle column C4 and the second row R2 may be selected. The selected nozzle unit NU of the fourth nozzle column C4 may be activated to a charge state in which the ink may be charged. The nozzle unit NU of the fourth nozzle column C4 and the second row R2 may be defined as the foregoing normal nozzle unit NNU. In this case, the first driving signal VS1 may be applied to the selected nozzle unit NU of the fourth nozzle column C4.

When grayscale data 3 D3 is provided to the seventh nozzle column C7, the nozzle unit NU of the seventh nozzle column C7 and the third row R3 may be selected. The selected nozzle unit NU of the seventh nozzle column C7 may be activated to a charge state in which the ink may be charged. The nozzle unit NU of the seventh nozzle column C7 and the third row R3 may be defined as the foregoing normal nozzle unit NNU. In this case, the first driving signal VS1 may be applied to the selected nozzle unit NU of the seventh nozzle column C7.

When grayscale data 4 D4 is provided to the second nozzle column C2, the nozzle unit NU of the second nozzle column C2 and the first row R1 may be selected. The selected nozzle unit NU of the second nozzle column C2 may be activated to a charge state in which the ink may be charged. The nozzle unit NU of the second nozzle column C2 and the first row R1 may be defined as the foregoing normal nozzle unit CNU. In this case, the second driving signal VS2 may be applied to the selected nozzle unit NU of the second nozzle column C2.

When grayscale data 5 D5 is provided to the fifth nozzle column C5, the nozzle unit NU of the fifth nozzle column C5 and the second row R2 may be selected. The selected nozzle unit NU of the fifth nozzle column C5 may be activated to a charge state in which the ink may be charged. The nozzle unit NU of the fifth nozzle column C5 and the second row R2 may be defined as the foregoing correction normal nozzle unit CNU. In this case, the second driving signal VS2 may be applied to the selected nozzle unit NU of the fifth nozzle column C5.

When grayscale data 6 D6 is provided to the eighth nozzle column C8, the nozzle unit NU of the eighth nozzle column C8 and the third row R3 may be selected. The selected nozzle unit NU of the eighth nozzle column C8 may be activated to a charge state in which the ink may be charged. The nozzle unit NU of the eighth nozzle column C8 and the third row R3 may be defined as the foregoing correction normal nozzle unit CNU. In this case, the second driving signal VS2 may be applied to the selected nozzle unit NU of the eighth nozzle column C8.

Other nozzle units NU of the first, second, fourth, fifth, seventh, and eighth nozzle columns C1, C2, C4, C5, C7, and C8 may be in an inactive state in which the ink INK is not discharged.

Hereinafter, the operations of the normal nozzle unit NNU of the first nozzle column C1 and the correction nozzle unit CNU of the second nozzle column C2 may be described as an example.

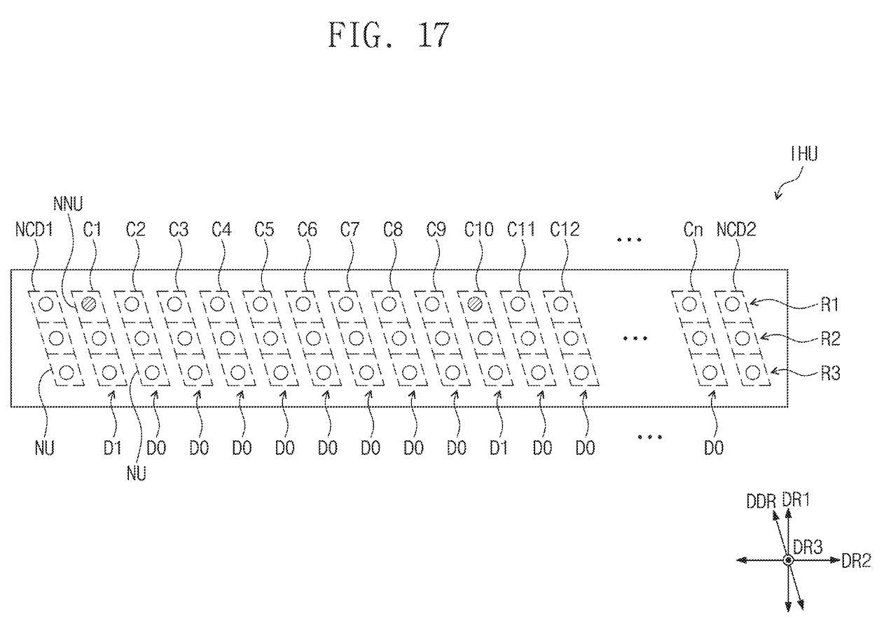

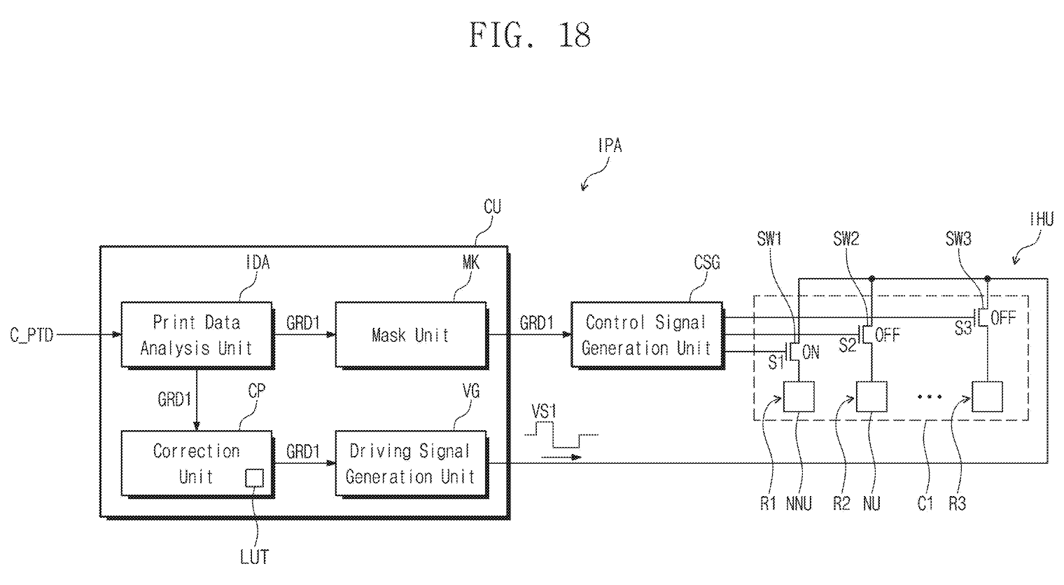

FIG. 17 is a drawing for explaining an operation for selecting the normal nozzle unit of the first nozzle column. FIG. 18 is a drawing for explaining an operation of the control unit shown in FIG. 14 when grayscale data 1 is provided to the control unit.

Referring to FIGS. 14, 17, and 18, the print data PTD may include the first grayscale data GRD1 and not include the correction data CPD. The compressed print data C_PTD may be provided to the print data analysis unit IDA. The print data analysis unit IDA may decompress the compressed print data C_PTD, and provide the first grayscale data GRD1 of the print data PTD to the mask unit MK and the correction unit CP.

The first grayscale data GRD1 may include grayscale data 1 D1. The first grayscale data GRD1 may be provided to the inkjet head unit IHU through the mask unit MK.

The inkjet head unit IHU may include first, second, and third switching elements SW1, SW2, and SW3 and a control signal generation unit (CSU). By way of an example, the nozzle units NU shown in FIG. 18 may be the nozzle units NU of the first nozzle column C1. According to some embodiments of the present disclosure, a nozzle column may be defined as an area in which the switching elements are located. Accordingly, the first, second, and third switching elements SW1, SW2, and SW3 may be located in the first nozzle column C1.

First terminals of the first, second, and third switching elements SW1, SW2, and SW3 may be commonly connected to the driving signal generation unit VG, and second terminals of the first, second, and third switching elements SW1, SW2, and SW3 may be respectively connected to the nozzle units NU (the forgoing piezoelectric elements). The second terminals of the first, second, and third switching elements SW1, SW2, and SW3 may be respectively connected to the foregoing piezoelectric elements PE. Control terminals of the first, second, and third switching elements SW may be connected to the control signal generation unit CSG.

The first switching element SW1 may be connected to a nozzle unit NU located at the first row R1 and the first nozzle column C1. The second switching element SW2 may be connected to a nozzle unit NU located at the second row R2 and the first nozzle column C1. The third switching element SW3 may be connected to a nozzle unit NU located at the third row R3 and the first nozzle column C1.

The control signal generation unit CSG may be provided with the first grayscale data GRD1 through the mask unit MK. The first grayscale data GRD1 may be provided to the first nozzle column C1 through the control signal generation unit CSG. For example, the first grayscale data GRD1 may be converted into first, second, and third signals S1, S2, and S3 by the control signal generation unit CSG to be provided to the first nozzle column C1.

The control signal generation unit CSG may be provided with grayscale data 1 D1 of the first grayscale data GRD1. The control signal generation unit CSG, in response to grayscale data 1 D1, may generate the first control signal S1 for turning on the first switching element SW1, the second control signal S2 for turning off the second switching element SW2, and the third control signal S3 for turning off the third switching element SW3.

The first switching element SW1 may be provided with the first control signal S1 from the control signal generation unit CSG to be turned on, and the second and third switching elements SW2 and SW3 may be provided with the second and third control signals S2 and S3 from the control signal generation unit CSG to be turned off. The normal nozzle unit NNU located at the first row R1 and the first nozzle column C1 may be connected to the driving signal generation unit VG by the turned-on first switching element SW1.

The print data PTD may include grayscale data 0 D0, and grayscale data 0 D0 may be provided to the second to ninth nozzle columns C1 to C9. Accordingly, the nozzle units NU of the second to ninth nozzle columns C1 to C9 may be in an inactive state in which the ink INK is not discharged.

The first grayscale data GRD1 may be provided to the driving signal generation unit VG through the correction unit CP. The driving signal generation unit VG, in response to the first grayscale data GRD1, may generate the first driving signal VS1 and provide the first driving signal VS1 to the normal nozzle unit NNU. The first driving signal VS1 may be provided to the normal nozzle unit NNU through the turned-on first switching element SW1.

The normal nozzle unit NNU may receive the applied first driving signal VS1, and, in response to the first driving signal VS1, discharge the first ink amount IV1 of ink INK. A state in which the normal nozzle unit NNU may be connected to the driving signal generation unit VG and receive the applied first driving signal VS1 to discharge the ink INK may be defined as the foregoing active state. Consequently, the normal nozzle unit NNU may be activated based on the first grayscale data GRD1. The first nozzle column C1 arranged with the normal nozzle unit NNU may be defined as a driving nozzle column.

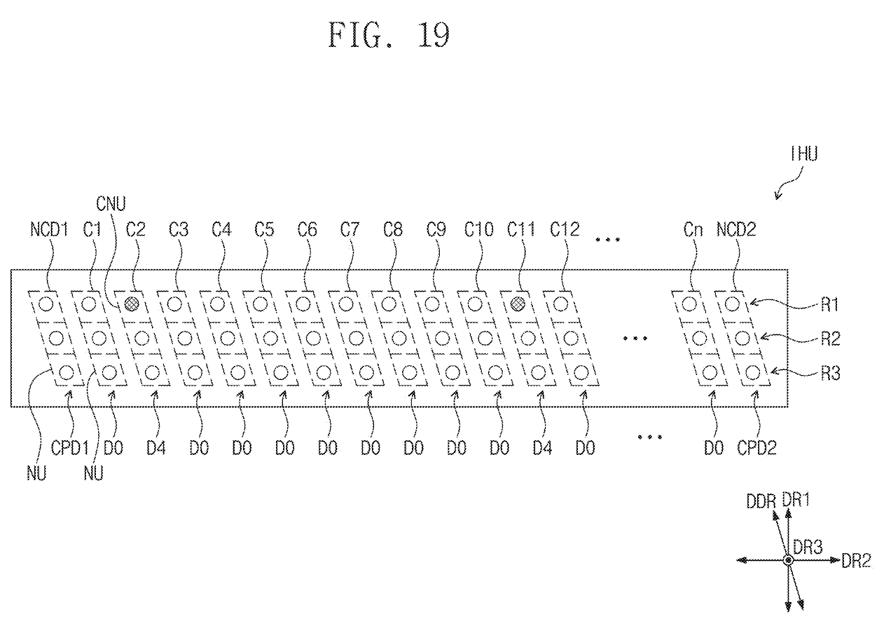

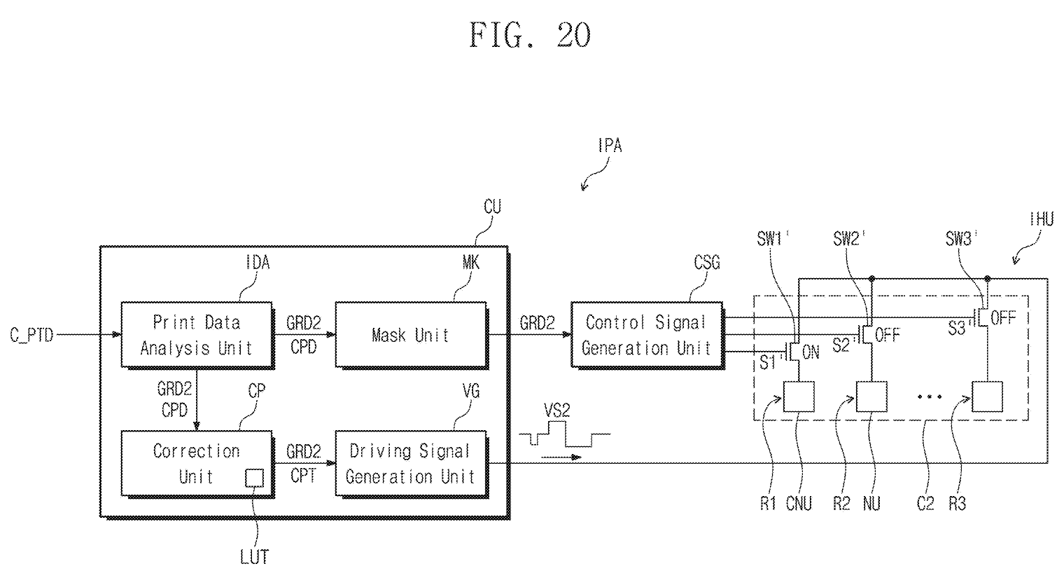

FIG. 19 is a drawing for explaining an operation for selecting the correction nozzle unit of the second nozzle column. FIG. 20 is a drawing for explaining an operation of the control unit shown in FIG. 14 when grayscale data 4 is provided to the control unit.

Referring to FIGS. 14, 19, and 20, the print data PTD may include the second grayscale data GRD2 and the correction data CPD. The compressed print data C_PTD may be applied to the print data analysis unit IDA, and the print data analysis unit IDA may decompress the compressed print data C_PTD and provide the second grayscale data GRD2 and the correction data CPD of the print data PTD to the mask unit ML and the correction unit CP.

The second grayscale data GRD1 may include grayscale data 4 D4. The second grayscale data GRD2 may be provided to the inkjet head unit IHU through the mask unit MK. As described above, the correction data CPD may be removed in the mask unit MK and not be provided to the inkjet head unit IHU.

The inkjet head unit IHU may include first, second, and third switching elements SW1’, SW2', SWb'. By way of an example, the nozzle units NU shown in FIG. 20 may be the nozzle units NU of the second nozzle column C2. The first, second, and third switching elements SW1’, SW2’, and SW3’ may be located in the second nozzle column C2.

A connection configuration of the first, second, and third switching elements SW1’, SW2’, and SW3’, the nozzle units NU of the second nozzle column C2, and the driving signal generation unit VG may be the same (or substantially the same) as the above-described configuration of the first, second, and third switching elements SW1, SW2, and SW3, the nozzle units NU of the first nozzle column C1, and the driving signal generation unit VG.

The control signal generation unit CSG may be provided with the second grayscale data GRD2 through the mask unit MK. The second grayscale data GRD2 may be provided to the second nozzle column C2 through the control signal generation unit CSG. For example, the second grayscale data GRD2 may be converted into first, second, and third signals S1’, S2’, and S3’ by the control signal generation unit CSG to be provided to the second nozzle column C2.

The control signal generation unit CSG may be provided with grayscale data 4 D4 of the second grayscale data GRD2. The control signal generation unit CSG, in response to the four grayscale data D4, may generate the first control signal S1’ for turning on the first switching element SW1’, the second control signal S2’ for turning off the second switching element SW2’, and the third control signal S3’ for turning off the third switching element SW3’.

The first switching element SW1’ may be provided with the first control signal S1’ to be turned on, and the second and third switching elements SW2’ and SW3’ may be provided with the second and third control signals S2’ and S3’ to be turned off. The correction nozzle unit CNU located at the first row R1 and the second nozzle column C2 may be connected to the driving signal generation unit VG by the turned-on first switching element SW1’.

Grayscale data 0 D0 may be provided to the first, third to ninth nozzle columns C0, C1 to C9. Accordingly, the nozzle units NU of the first, third to ninth nozzle columns C1, C3 to C9 may be in an inactive state in which the ink INK is not discharged.

The second grayscale data GRD2 may be provided to the driving signal generation unit VG through the correction unit CP. The correction unit CP may provide, to the driving signal generation unit VG, the correction parameter CPT corresponding to the received correction data CPD.

The driving signal generation unit VG, in response to the second grayscale data GRD2, generates a driving signal (e.g., the first and second pulses PS1 and PS2), wherein the second driving signal VS2 may be generated by adding the foregoing preliminary PPS to the driving signal based on the correction parameter CPT. The driving signal generation unit VG may provide the second driving signal VS2 to the correction nozzle unit CNU. The second driving signal VS2 may be provided to the correction nozzle unit CNU through the turned-on second switching element SW2.

The correction nozzle unit CNU may receive the applied second driving signal VS2, and in response to the second driving signal VS2, discharge the second amount IV2 of the ink INK. A state in which the correction nozzle unit CNU may be connected to the driving signal generation unit VG and receive the applied second driving signal VS2 to discharge the ink INK may be defined as the foregoing active state. Consequently, the correction nozzle unit CNU may be activated based on the second grayscale data GRD2.

The second nozzle column C2 arranged with the correction nozzle unit CNU may be defined as a correction driving nozzle column. Accordingly, the driving nozzle column defined with the first nozzle column C1 and the correction driving nozzle column defined with the second nozzle column C2 may be adjacent to each other in the second direction DR2.

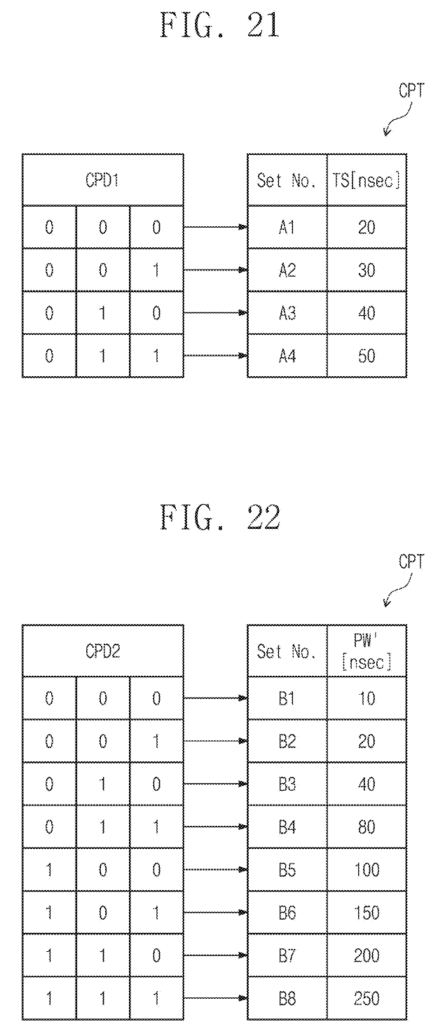

FIG. 21 shows, as a table, first correction data and first correction values of the correction parameter. FIG. 22 shows, as a table, second correction data and second correction values of the correction parameter.

Referring to FIGS. 21 and 22, by way of an example, the first correction data CPD1 may have 3-bit values of "000", "001", "010", and "011”. By way of an example, the second grayscale data CPD2 may have 3-bit values of "000", "001", "010", "011", "100", "101", "110", and "111”.

The correction parameter CPT may include a plurality of first correction values A1 to A4 and a plurality of second correction values B1 to B8. The first correction values A1 to A4 may be defined as values for setting the timing shift period TS. The second correction values B1 to B8 may be defined as values for setting the width PW’ of the preliminary pulse PPS. The first correction values A1 to A4 and the second correction values B1 to B8 may be stored in the look-up table LUT.

"000", "001", "010", and "011”of the first correction data CPD1 may respectively correspond to the first correction values A1, A2, A3, and A4. "000", "001", "010", "011", "100", "101", "110", and "111” of the second correction data CPD2 may respectively correspond to the second correction values B1,B2,B3,B4,B5,B6,B7, and B8.

The first correction data CPD1 and the second correction data CPD2 may be provided to the correction unit CP. The correction unit CP may provide, to the driving signal generation unit VG, the first correction value corresponding to the first correction data CPD1 and the second correction value corresponding to the second correction data CPD2. For example, when “011” of the first correction data CPD1 and “101”of the second correction data CPD2 are provided to the correction unit CP, the first correction value A4 (50 nanoseconds (nsec) (or about 50 nsec)) of the first correction data CPD1 and the second correction value B6 (150 nsec or about 150 nsec) corresponding to “101” of the second correction data CPD2 may be provided to the driving signal generation unit VG.

The driving signal generation unit VG may generate the second driving signal VS2 so that the second driving signal has the timing shift period TS having the first correction value A4 (50 nsec or about 50 nsec) and the width PW’ having the second correction value B6 (150 nsec or about 150 nsec). Therefore, according to the first correction values A1 to A4 and the second correction values B1 to B8, the timing shift period TS of the second driving signal VS2 and the width PW’ of the preliminary pulse PPS may be set in various ways.

As the first correction values A1 to A4 are smaller, the timing shift period TS may be relatively reduced. Accordingly, the second ink amount IV2 discharged from the correction nozzle unit CNU may increase. As the second correction values B1 to B8 are greater, the width PW’ may increase. Accordingly, the second ink amount IV2 discharged from the correction nozzle unit CNU may increase.

Referring to FIGS. 9, 11A, 11B, 12A to 12C, 18, and 20, a target ink amount for forming the emission layer EML may be set. The normal nozzle unit NNU and the correction nozzle unit CNU may be used for forming the emission layer EML of the same light-emitting element OLED.

By way of an example, the target ink amount for forming the emission layer EML may be set to 110 pL, the normal nozzle unit NNU may discharge the first ink amount IV1 of 4 pL, and the correction nozzle unit CNU may discharge the second ink amount IV2 of 4.2 pL.

When only the normal nozzle unit NNU is used, the normal nozzle unit NNU discharges the ink INK 28 times to form the emission layer EML. In this case, the target ink amount may be 110 pL, but the total ink amount discharged to the light-emitting area LA may be 112 pL. Accordingly, an error of 2 pL may occur.

According to some embodiments of the present disclosure, the normal nozzle unit NNU and the correction nozzle unit CNU are used together to discharge the ink INK to the light-emitting area LA. The normal nozzle unit NNU moves onto the light-emitting area LA to discharge the ink INK plural times, and then the correction nozzle unit CNU moves onto the light-emitting area LA to discharge the ink INK plural times.

The normal nozzle unit NNU discharges the ink INK to the light-emitting area INK 17 times, and the correction nozzle unit CNU discharges the ink INK to the light-emitting area INK 10 times. In this case, since a total ink amount discharged to the light-emitting area LA is 110 pL, the total ink amount may be the same as the target ink amount. Accordingly, the normal nozzle unit NNU and the correction nozzle unit CNU are used together to provide the target ink amount to the light-emitting area LA more precisely.

Since the sizes of a red pixel, a green pixel, and a blue pixel are different from each other, the ink amount discharged from the normal nozzle unit NNU may be set in various ways according to the correction parameter and the red pixel, green pixel and blue pixel may be manufactured. In addition, when the various display devices DD are manufactured, the sizes of the pixels may be different in case where the resolutions of the display devices DD are different. In this case, the display devices DD may be manufactured by setting the ink amount discharged from the normal nozzle unit CNU in various ways according to the correction parameter.

By way of an example, the compensation nozzle units CNU located at the second nozzle column C2 and the first row R1, the second row R2 of the fifth nozzle column C5, and the third row R3 of the eighth nozzle column C8 may discharge the same ink amount. However, embodiments according to the present disclosure are not limited thereto and the correction nozzle units CNU may discharge different amounts of ink.

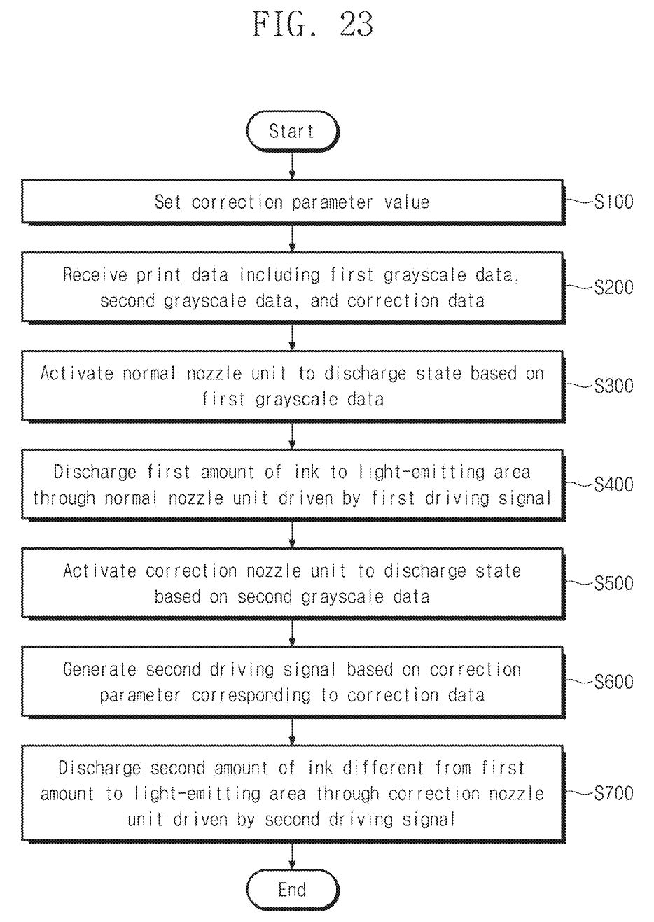

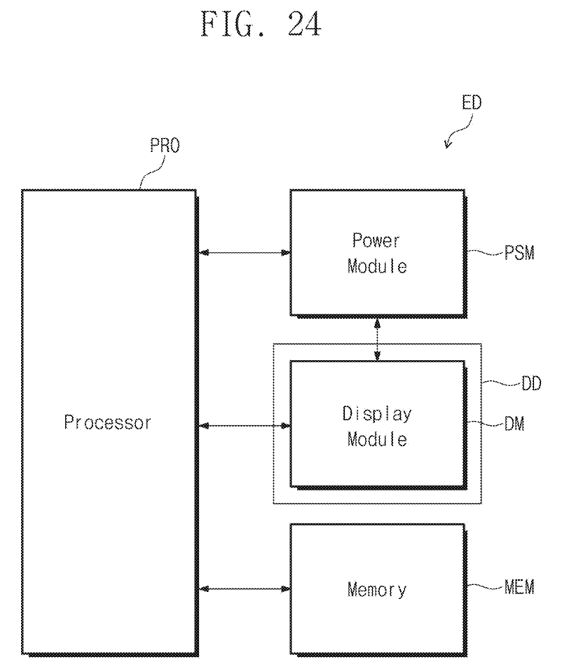

FIG. 23 is a flowchart for explaining aspects of an inkjet printing method using an inkjet printing apparatus according to some embodiments of the present disclosure. Although FIG. 23 illustrates various operations in an inkjet printing method according to some embodiments, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

Referring to FIG. 23, in operation S100, the correction parameter CPT may be set. For example, the first correction values A1 to A4 and the second correction values B1 to B8 may be determined in advance in order to set the timing shift period TS and the width PW’ of the preliminary pulse PPS in various ways, and may be stored in the correction unit CP as the correction parameter CPT.

In operation S200, the print data PTD including the first grayscale data GRD1, the second grayscale data GRD2, and the correction data CPD may be received. The foregoing control unit CU may receive the print data PTD (e.g., compressed data).

In operation S300, the normal nozzle unit NNU may be activated to a discharge state based on the first grayscale data GRD1. In operation S400, the first amount IV1 of ink INK may be discharged to the light-emitting area LA through the normal nozzle unit NNU driven by the first driving signal VS1.

In operation S500, the correction nozzle unit CNU may be activated to a discharge state based on the second grayscale data GRD2. In operation S600, the second driving signal VS2 may be generated based on the correction parameter CPT corresponding to the correction data CPD. In operation S700, the second amount IV2 of the ink INK may be discharged to the light-emitting area LA through the correction nozzle unit CNU driven by the second driving signal VS2.

FIG. 24 is a block diagram of an electronic device including a display device including light-emitting elements manufactured by an inkjet printing apparatus according to some embodiments of the present disclosure.

Referring to FIG. 24, the electronic device according to some embodiments may include the display device DD configured to provide an image to a user, and may further include a module or device having an additional function other than the display device DD. The electronic device ED according to some embodiments may include a display device DD, a processor PRO, a memory MEM, and a power supply module PSM, and the display device DD may include a display module DM.

The processor PRO may include at least one of a central processing unit (CPU), an application processor (AP), a graphic processing unit (GPU), a communication processor (CP), an image signal processor (ISP), or a controller.

The processor PRO may process an image signal to provide the processed image signal to the display device DD. The display device DD may be provided with the image signal from the processor PRO, and provide a user with an image corresponding to the image signal.

The processor PRO may be electrically connected to the display module DM of the display device DD through a flexible circuit board, a connector, and the like. The display module DM may display the image based on data received from the processor PRO.

According to some embodiments of the present disclosure, the processor PRO may be divided into two or more and provided in a functional or structural view. For example, the processor PRO may include a main processor in a first driving chip type including the CPU, and an auxiliary processor in a second driving chip type including a controller configured to receive an image signal from the main processor to process the image signal so as to be matched with an interface specification of the display module DM.

The memory MEM may store data information required for an operation of the processor PRO or the display module DM. When the processor PRO executes an application stored in the memory MEM, the image signal and/or an input control signal are/is transferred to the display module DM and the display module DM may process the received image signal and output image information through a display screen.

The power supply module PSM may include a power supply module such as a power adapter or a battery device, and a power conversion module configured to generate power required for an operation of the electronic device ED.

At least one of each component of the foregoing electronic device ED may be included in the display device DD according to the foregoing embodiments. In addition, some of individual modules included functionally in one module may be included in the display device DD, and the other may be provided separately from the display device DD. For example, the electronic device DD may include the display module DM, and the processor PRO, the memory MEM, and the power supply module PSM may be provided in other device types in the electronic device ED other than the display device DD.

The display device DD may include the light-emitting element OLED manufactured by the inkjet printing method using the foregoing inkjet printing apparatus IPA.

FIG. 25 is schematic diagrams of an electronic device according to various embodiments.

Referring to FIG. 25, the display device DD according to some embodiments of the present disclosure may be applied to various electronic devices. For example, the various electronic devices to which the display device DD according to some embodiments is applied may include electronic devices for image display such as a smartphone 10_1a, a tablet PC 10_1b, a laptop computer 10_1c, a TV 10_1d, a desktop monitor 10_1e, or the like.

In addition, the various electronic devices to which the display device DD according to some embodiments is applied may include wearable electronic devices such as smart glasses 10_2a, a head mount display 10_2b, a smart watch 10_2c, or the like. In addition, the various electronic devices to which the display device DD according to some embodiments is applied may include vehicle electronic devices 10_3 such as a car dashboard, a center fascia, a center information display (CID) located on the dashboard, a room mirror display, or the like.

According to some embodiments of the present disclosure, a normal nozzle unit configured to discharge ink with a first ink amount, and a correction nozzle unit configured to discharge ink with a second ink amount may be used together to discharge the ink to an emission area. Accordingly, a target ink amount may be provided relatively more precisely to the light-emitting area to form an emission layer.

Although aspects of some embodiments of the present disclosure are described above, various modifications and variation can be made without departing from the spirit or technical scope of embodiments according to the present disclosure as defined by the appended claims, and their equivalents.

Accordingly, the technical scope of embodiments according to the present disclosure should not be limited to the content described in the specification, but should be defined by the appended claims, and their equivalents.

What is claimed is:

1. An inkjet printing apparatus comprising:
a normal nozzle unit configured to discharge a first amount of ink in response to a first driving signal;
a correction nozzle unit configured to discharge a second amount of the ink different from the first amount in response to a second driving signal;
a driving signal generation unit configured to generate the first driving signal and the second driving signal to provide the first driving signal and the second driving signal to the normal nozzle unit and the correction nozzle unit; and
a correction unit configured to receive a correction data and to provide a correction parameter corresponding to the correction data to the driving signal generation unit,
wherein the driving signal generation unit is configured to generate the second driving signal based on the correction parameter.

2. The inkjet printing apparatus of claim 1,
wherein the second driving signal comprises, successively, a preliminary pulse, a first pulse, and a second pulse,
wherein the preliminary pulse has a lower level than a reference voltage, the first pulse has a higher level than the reference voltage, and the second pulse has a lower level than the reference voltage.

3. The inkjet printing apparatus of claim 2,
wherein the first driving signal comprises the successive first pulse and second pulses.

4. The inkjet printing apparatus of claim 2,
wherein based on the preliminary pulse being applied to the correction nozzle unit, the correction nozzle unit is configured to not discharge the ink, and
based on the second pulse being applied to the correction nozzle unit, the correction nozzle unit is configured to discharge the ink.

5. The inkjet printing apparatus of claim 2,
wherein a pulse application time is defined as a width of a pulse, and a width of the preliminary pulse is smaller than that of the second pulse.

6. The inkjet printing apparatus of claim 2,
wherein an amplitude of the preliminary width is smaller than that of the second pulse.

7. The inkjet printing apparatus of claim 2,
wherein a width of the preliminary pulse defined as an application time of the preliminary pulse and a timing shift period between the preliminary pulse and the first pulse are adjusted with the correction parameter.

8. The inkjet printing apparatus of claim 7,
wherein the correction parameter comprises:
a plurality of first correction values for setting the timing shift period; and
a plurality of second correction values for setting the width of the preliminary pulse.

9. The inkjet printing apparatus of claim 8,
wherein as the first correction values are smaller, the timing shift period is reduced and the second ink amount increases.

10. The inkjet printing apparatus of claim 8,
wherein as the second correction values are larger, the width of the preliminary pulse increases and the second ink amount increases.

11. The inkjet printing apparatus of claim 1,
wherein the second ink amount is more than the first ink amount.

12. The inkjet printing apparatus of claim 1,
further comprising an inkjet head unit comprising a plurality of nozzle units in each of a plurality of columns,
wherein the columns comprise:
a first non-discharge nozzle column;
a second non-discharge nozzle column; and
a plurality of nozzle columns arranged between the first non-discharge nozzle column and the second non-discharge nozzle column,
wherein the nozzle columns comprise:
a driving nozzle column comprising the normal nozzle unit; and
a correction driving nozzle column comprising the correction nozzle unit.

13. The inkjet printing apparatus of claim 12,
wherein the driving nozzle column and the correction driving nozzle column are adjacent to each other, and
the first non-discharge nozzle column and the second non-discharge nozzle column are adjacent to both sides of the inkjet head unit.

14. The inkjet printing apparatus of claim 12, further comprising:
a print data analysis unit configured to receive a compressed print data comprising a first grayscale data, a second grayscale data, and the correction data, and to decompress the compressed print data to output print data; and
a mask unit configured to be provided with the print data from the print data analysis unit, and mask to block the correction data,
wherein the driving nozzle column is configured to receive the first grayscale data through the mask unit, the correction driving nozzle column is configured to receive the second grayscale data through the mask unit, and the correction unit is configured to receive the correction data.

15. The inkjet printing apparatus of claim 14,
wherein the normal nozzle unit is configured to be activated based on the first grayscale data to a discharge state in which the ink is dischargeable.

16. The inkjet printing apparatus of claim 14,
wherein the correction nozzle unit is configured to be activated based on the second grayscale data to a discharge state in which the ink is dischargeable.

17. The inkjet printing apparatus of claim 13,
wherein the correction data is not provided to the first and second non-discharge nozzle columns, and the nozzle units of the first and second non-discharge nozzle columns do not discharge the ink.

18. The inkjet printing apparatus of claim 13,
wherein the nozzle unit and the correction nozzle unit are configured to discharge the ink to a light-emitting area for providing an emission layer of a same light-emitting element.

19. An inkjet printing method comprising:
setting a correction data;
receiving print data comprising a first grayscale data, a second grayscale data, and the correction data;
activating a normal nozzle unit to a discharge state based on the first grayscale data;
discharging a first amount of ink to a light-emitting area of a light-emitting element through the normal nozzle unit driven by a first driving signal;
activating a correction nozzle unit to a discharge state based on the second grayscale data;
generating a second driving signal based on a correction parameter corresponding to the correction data; and
discharging a second amount of the ink different from the first amount to the light-emitting area through the correction nozzle unit driven by the second driving signal.

20. An electronic device comprising a display device configured to display an image,
wherein the display device comprises a light-emitting element manufactured by an inkjet printing method,
wherein the inkjet printing method comprises:
setting a correction data;
receiving print data comprising a first grayscale data, a second grayscale data, and the correction data;
activating a normal nozzle unit to a discharge state based on the first grayscale data;
discharging a first amount of ink to a light-emitting area of a light-emitting element through the normal nozzle unit driven by a first driving signal;
activating a correction nozzle unit to a discharge state based on the second grayscale data;
generating a second driving signal based on a correction parameter corresponding to the correction data; and
discharging a second amount of the ink different from the first amount to the light-emitting area through the correction nozzle unit driven by the second driving signal.
